(19) United States
(12) Patent Application Publication
(10) Pub. No.: US 2013/0105810 A1
(43) Pub. Date: May 2, 2013

(54) COMPOUND SEMICONDUCTOR DEVICE, METHOD FOR MANUFACTURING THE SAME, AND ELECTRONIC CIRCUIT

(71) Applicants: Masato Nishimori, Atsugi (JP); Toshihiro Ohki, Hadano (JP); Toshihide Kikkawa, Machida (JP)

(72) Inventors: Masato Nishimori, Atsugi (JP); Toshihiro Ohki, Hadano (JP); Toshihide Kikkawa, Machida (JP)

(73) Assignee: FUJITSU LIMITED, Kawasaki-shi (JP)

(21) Appl. No.: 13/613,158

(22) Filed: Sep. 13, 2012

(30) Foreign Application Priority Data
Nov. 2, 2011 (JP) 2011-241703

(51) Int. Cl. H01L 29/20; H01L 29/06; H01L 21/20

(52) U.S. Cl. 257/76; 438/478; 257/655; 257/E29.089; 257/E21.09; 257/E29.005

(57) ABSTRACT

A compound semiconductor device includes: a first compound semiconductor layer in which carriers are formed; a second compound semiconductor layer, provided above the first compound semiconductor layer, to supply the carriers; and a third compound semiconductor layer provided above the second compound semiconductor layer, wherein the third compound semiconductor layer includes a area that has a carrier concentration higher than a carrier concentration of the second compound semiconductor layer.

### CROSS-REFERENCE TO RELATED APPLICATION(S)

This application is based upon and claims the benefit of priority of the prior Japanese Patent Application No. 2011-241703, filed on Nov. 2, 2011, the entire contents of which are incorporated herein by reference.

### FIELD

The embodiments discussed herein are related to a compound semiconductor device, a method for manufacturing the compound semiconductor device, and an electronic circuit.

### BACKGROUND

Nitride semiconductors have properties such as high saturated electron drift velocity and a wide band gap, and are used in high-voltage, high-power semiconductor devices. For example, gallium nitride (GaN), a nitride semiconductor, has a band gap of 3.4 eV, which is greater than both the band gap (1.1 eV) of silicon (Si) and the band gap (1.4 eV) of gallium arsenic (GaAs), and also has high breakdown field strength. Therefore, GaN is used as a material for semiconductor devices that are used in power supplies that reach high-voltage operation and high power.

Related art is disclosed in Japanese Laid-open Patent Publication No. 2010-278150, Japanese Laid-open Patent Publication No. 2006-134935, International Publication Pamphlet No. WO 2007/108055, or the like.

### SUMMARY

According to one aspect of the embodiment, a compound semiconductor device includes: a first compound semiconductor layer in which carriers are formed; a second compound semiconductor layer, provided above the first compound semiconductor layer, to supply the carriers; and a third compound semiconductor layer provided above the second compound semiconductor layer, wherein the third compound semiconductor layer includes a area that has a carrier concentration higher than a carrier concentration of the second compound semiconductor layer.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIGS. 1A to 1C illustrate an exemplary method for manufacturing a compound semiconductor device;

FIGS. 2A to 2C illustrate an exemplary method for manufacturing a compound semiconductor device;

FIGS. 3A to 3C illustrate an exemplary method for manufacturing a compound semiconductor device;

FIG. 4 illustrates an exemplary method for manufacturing a compound semiconductor device;

FIG. 5 illustrates an exemplary band diagram;

FIG. 6 illustrates an exemplary band diagram;

FIGS. 7A and 7B illustrate an exemplary method for manufacturing a compound semiconductor device;

FIGS. 8A and 8B illustrate an exemplary method for manufacturing a compound semiconductor device;

FIGS. 9A to 9C illustrate an exemplary method for manufacturing a compound semiconductor device;

FIGS. 10A to 10C illustrate an exemplary method for manufacturing a compound semiconductor device;

FIGS. 11A to 11C illustrate an exemplary method for manufacturing a compound semiconductor device;

FIGS. 12A to 12C illustrate an exemplary method for manufacturing a compound semiconductor device;

FIGS. 13A to 13C illustrate an exemplary method for manufacturing a compound semiconductor device;

FIGS. 14A and 14B illustrate an exemplary method for manufacturing a compound semiconductor device;

FIGS. 15A to 15C illustrate an exemplary method for manufacturing a compound semiconductor device;

FIGS. 16A and 16B illustrate an exemplary method for manufacturing a compound semiconductor device;

FIGS. 17A to 17C illustrate an exemplary relationship between a drain voltage and a drain current;

FIGS. 18A to 18C illustrate an exemplary method for manufacturing a compound semiconductor device;

FIGS. 19A to 19C illustrate an exemplary method for manufacturing a compound semiconductor device;

FIG. 20 illustrates an exemplary power supply apparatus; and

FIG. 21 illustrates an exemplary high-frequency amplifier.

### DESCRIPTION OF EMBODIMENTS

Field-effect transistors, for example, high electron mobility transistors (HEMTs), use nitride semiconductors. For example, in an aluminium gallium nitride/gallium nitride HEMT (AlGaN/GaN HEMT), which is a type of GaN-based HEMT (GaN-HEMT), GaN is used as an electron transit layer and AlGaN is used as an electron supply layer. In a AlGaN/GaN HEMT, a highly-concentrated two-dimensional electron gas (2DEG) is obtained due to the spontaneous polarization of AlGaN as well as piezoelectric polarization induced in AlGaN by strain due to the difference in lattice parameters between GaN and AlGaN. Therefore, a AlGaN/GaN HEMT may possibly be used as a high-efficiency switching element or a high-voltage power device for electric vehicles and the like.

In a high-electron mobility transistor (HEMTs) that is made of a nitride semiconductor, the drain current decreases when operating at high drain voltages (this phenomenon is hereinafter referred to as “current collapse”). Current collapse is caused by trap levels present on the surface of a semiconductor. The stronger the electric field, which is located between the gate electrode and the drain electrode and which is concentrated at the edge of the gate electrode and the edge of the drain electrode, the less the drain current is. Device properties deteriorate due to current collapse.

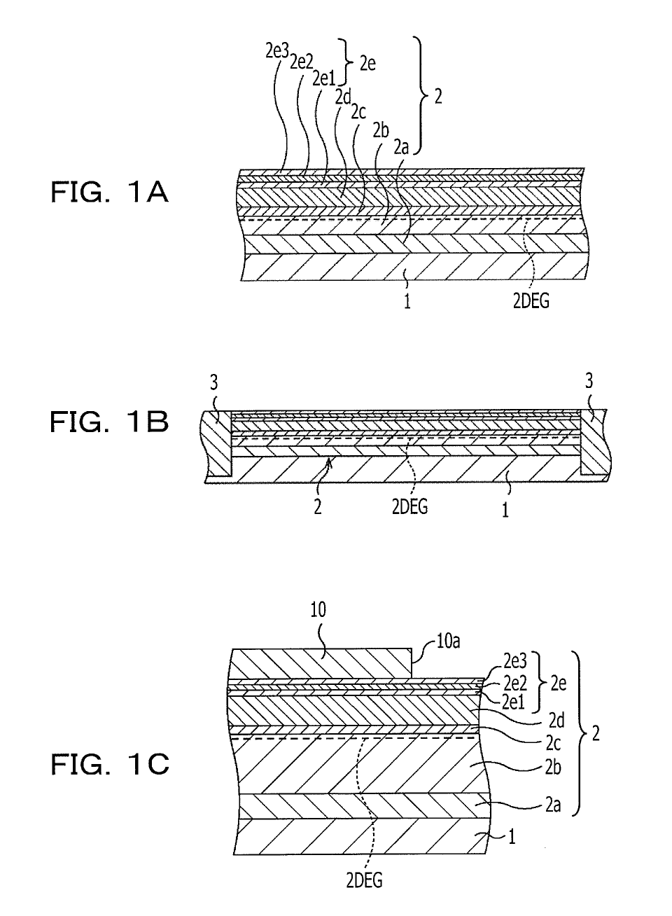

FIGS. 1A to 1C, 2A to 2C, and 3A to 3C illustrate an exemplary method for manufacturing a compound semiconductor device. The compound semiconductor device may be, for example, a Schottky-type AlGaN/GaN HEMT.

As illustrated in FIG. 1A, a compound semiconductor multilayer structure 2 is formed on a substrate for growth, for example a silicon carbide (SiC) substrate 1. Examples of a substrate for growth may include SiC substrates, silicon substrates, sapphire substrates, GaAs substrates, and GaN substrates. The substrate may be semi-insulating or conductive. The compound semiconductor multilayer structure 2 includes a buffer layer 2a, an electron transit layer 2b, an intermediate layer 2c, an electron supply layer 2d, and a capping layer 2e.

During an operation of the compound semiconductor device, a two-dimensional electron gas (2DEG) is generated in a vicinity of a interface with the electron supply layer 2d, for example, the intermediate layer 2c in the electron transit layer 2b. The 2DEG is generated based on the difference in lattice parameters between a compound semiconductor the electron transit layer 2b, for example, GaN and a compound semiconductor of the electron supply layer 2d, for example, AlGaN.

Each compound semiconductor is grown on the SiC substrate 1 by, for example, metalorganic vapor phase epitaxy (MOVPE). Molecular beam epitaxy (MBE) or the like may be used instead of MOVPE. The compound semiconductors that correspond to the buffer layer 2a, the electron transit layer 2b, the intermediate layer 2c, the electron supply layer 2d, and the capping layer 2e respectively are deposited in series over the SiC substrate. The buffer layer 2a is formed using aluminium nitride (AlN) so as to have a thickness of about 5 nm. The electron transit layer 2b is formed using undoped GaN (i-GaN) so as to have a thickness of about 1 μm. The intermediate layer 2c is formed using i-AlGaN (i-Al_{0.25}Ga_{0.75}N) so as to have a thickness of about 5 nm. The electron supply layer 2d is formed using n-AlGaN so as to have a thickness of about 20 nm. The capping layer 2e has a multilayer structure that includes three compound semiconductor sub-layers and is formed in such a manner that an n-GaN sub-layer 2e1 having a thickness of about 5 nm, an AlN sub-layer 2e2 having a thickness of about 3 nm, and an n-GaN sub-layer 2e3 having a thickness of about 3 nm are deposited in that order. AlGaN may be used to form the buffer layer 2a instead of AlN, or the buffer layer 2a may be formed in such a manner that GaN is grown by low-temperature epitaxy.

A mixture of trimethylaluminium (TMAI) gas, which is an aluminium source, and ammonia (NH₃) gas may be used as a source gas to grow AlN. A mixture of trimethylgallium (TMGa) gas, which is a gallium source, and NH₃ gas may be used as a source gas to grow GaN. A mixture of TMAI gas, TMGa gas, and NH₃ gas may be used as a source gas to grow AlGaN. The supply and flow rate of each of the TMAI gas and the TMGa gas may be appropriately set depending on which compound semiconductor layer is to be grown. The flow rate of the NH₃ gas, which is a common gas, may be about 100 sccm to 10 LM. The growth pressure may be about 50 Torr to 300 Torr. The growth temperature may be about 1,000° C. to 1,200° C.

When AlGaN and GaN is formed as a n-type, for example, when the electron supply layer 2d (n-AlGaN) and the n-GaN sub-layers 2e1 and 2e3 is formed, an n-type impurity is added to the source gas. For example, after silane (SiH₄) gas, which contains silicon, is added to each source gas at a given flow rate, the AlGaN and GaN are doped with silicon. The doping concentration of silicon may be, for example, about 2×10¹⁸ cm⁻³.

As illustrated in FIG. 1B, an isolation structure 3 is formed. The isolation structure 3 may possibly be omitted in FIG. 1C and figures subsequent thereto. For example, argon is implanted into an isolation region of the compound semiconductor multilayer structure 2. The isolation structure 3 is formed in the compound semiconductor multilayer structure 2 and a surface portion of the SiC substrate 1. The isolation structure 3 demarcates an active region on the compound semiconductor multilayer structure 2. The isolation structure 3 may be formed by, for example, a shallow trench isolation (STI) process. For example, a chlorine-based etching gas may be used to dry-etch the compound semiconductor multilayer structure 2.

As illustrated in FIG. 1C, a photoresist mask 10 is formed. A photoresist is applied to the capping layer 2e of the compound semiconductor multilayer structure 2 and a given portion that includes a planned site for a drain electrode 5 is opened through irradiation with ultraviolet light. A photoresist mask 10 is formed on the capping layer 2e so as to have an opening 10a that exposes the given portion, which includes the planned site for the drain electrode 5. In the opening 10a, a surface portion of the capping layer 2e that includes the planned site for the drain electrode 5 and a range extending about 1 μm from an end thereof toward a planned site for a gate electrode 6 are exposed.

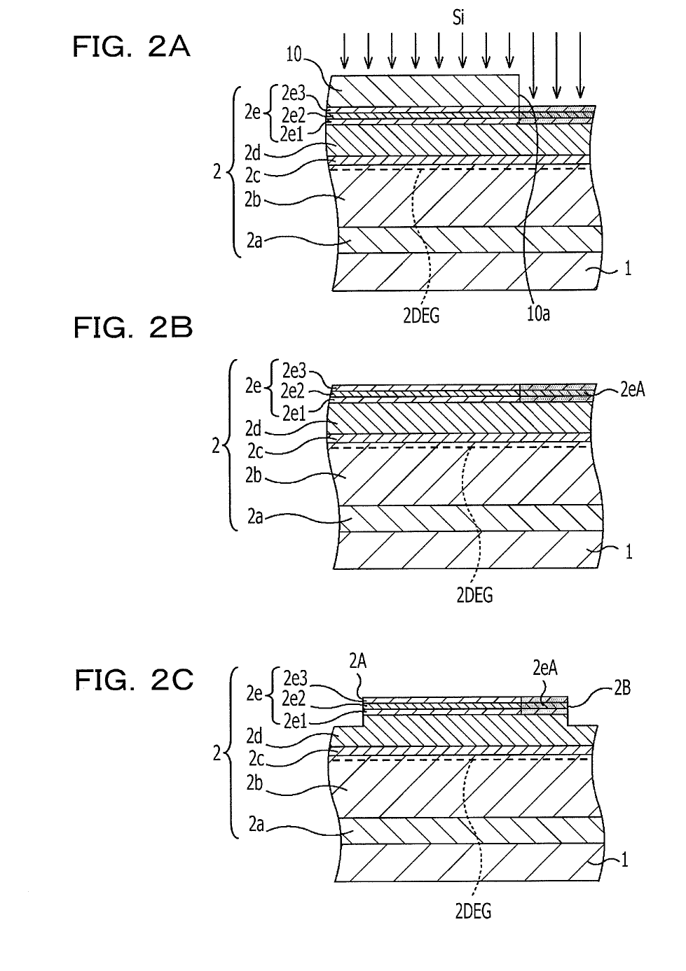

As illustrated in FIG. 2A, the capping layer 2e of the compound semiconductor multilayer structure 2 is doped with an n-type impurity. The n-type impurity is ion-implanted into a surface portion of the capping layer 2e that is exposed through the opening 10a through the use of the photoresist mask 10. The n-type impurity is silicon and is implanted at a dose of about 5×10¹² cm⁻² to 1×10¹⁶ cm⁻², for example about 1×10¹³ cm⁻², with an acceleration energy so that a peak of concentration distribution is located in the n-GaN sub-layer 2e1 of the capping layer 2e. The implanted n-type impurity may alternatively be germanium, oxygen, or the like. When the dose of the n-type impurity is less than about 5×10¹² cm⁻², a carrier concentration higher than the carrier concentration of the electron supply layer 2d may fail to be obtained. When the dose of the n-type impurity is more than about 1×10¹⁶ cm⁻², crystal defects are caused by damage due to ion implantation and therefore current collapse may possibly be worsened. When setting the dose of the n-type impurity to about 5×10¹² cm⁻² to 1×10¹⁶ cm^{×2}, the occurrence of crystal defects is reduced and a carrier concentration higher than the carrier concentration of the electron supply layer 2d may be obtained.

As illustrated in FIG. 2B, a highly-concentrated n-type site 2eA is formed in the capping layer 2e. The photoresist mask 10 is removed by ashing or wet etching using a given chemical solution. The capping layer 2e is annealed. Silicon implanted in the capping layer 2e is activated, and then the highly-concentrated n-type site 2eA is locally formed in the capping layer 2e. The highly-concentrated n-type site 2eA may have a carrier concentration higher than the carrier concentration of the electron supply layer 2d and an energy level lower than the Fermi energy.

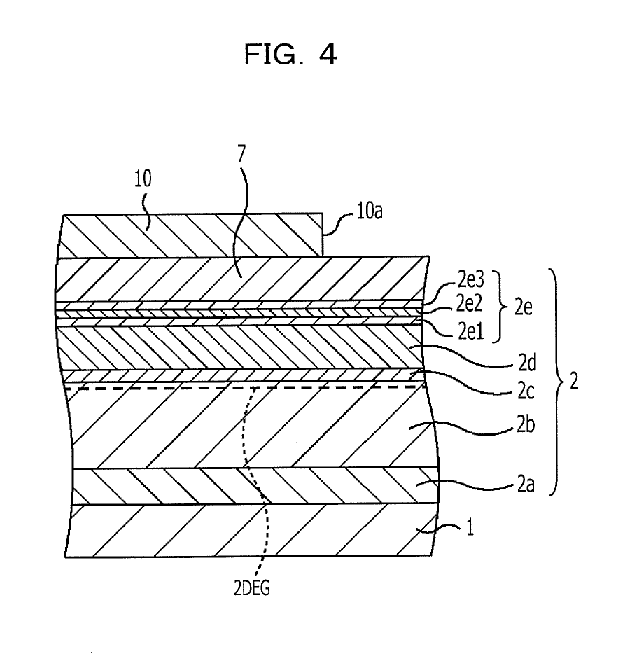

FIG. 4 illustrates an exemplary method for manufacturing a compound semiconductor device. In order to control the peak of the concentration distribution of silicon, a film as an implantation mask 7 for silicon, for example, silicon nitride (SiN) (or silicon dioxide (SiO₂) or the like) may be formed on the capping layer 2e so as to have a thickness of about 20 nm to 30 nm as illustrated in FIG. 4. A photoresist mask 10 is formed on the implantation mask 7. Similar to FIG. 2A, Si is implanted so that the peak of the concentration distribution thereof is located in the n-GaN sub-layer 2e1 of the capping layer 2e. Similar to FIG. 2B, the photoresist mask 10 and the implantation mask 7 are removed and a high-concentration n-type site 2eA is formed by the activation annealing of silicon.

As illustrated in FIG. 2C, an electrode recess 2A and an electrode recess 2B are formed in a planned site for a source electrode 4 and a planned site for the drain electrode 5, respectively, the planned sites being located on a surface of the compound semiconductor multilayer structure 2. A photoresist is applied to the surface of the compound semiconductor multilayer structure 2. The photoresist is processed by lithography, whereby openings are formed in the photoresist so that surface portions of the compound semiconductor multilayer structure 2 that correspond to the planned sites (planned electrode sites) for the source electrode 4 and the drain electrode 5 are exposed through the openings. A photoresist mask having the openings is formed.

Using the photoresist mask, portions of the capping layer 2e and the electron supply layer 2d that correspond to the planned electrode sites are removed by dry etching until surface portions of the electron supply layer 2d are removed. The electrode recesses 2A and 2B, which expose the planned electrode sites of the electron supply layer 2d, are formed. For etching conditions, an inert gas such as argon and a chlorine-based gas such as Cl₂ are used as etching gases. For example, the flow rate of Cl₂ may be 30 sccm, the pressure thereof may be 2 Pa, and the input RF power may be 20 W. In the electrode recesses 2A and 2B, the capping layer 2e may be etched until intermediate portions thereof are exposed or surface portions of the electron supply layer 2d are exposed. The photoresist mask is removed by ashing or the like.

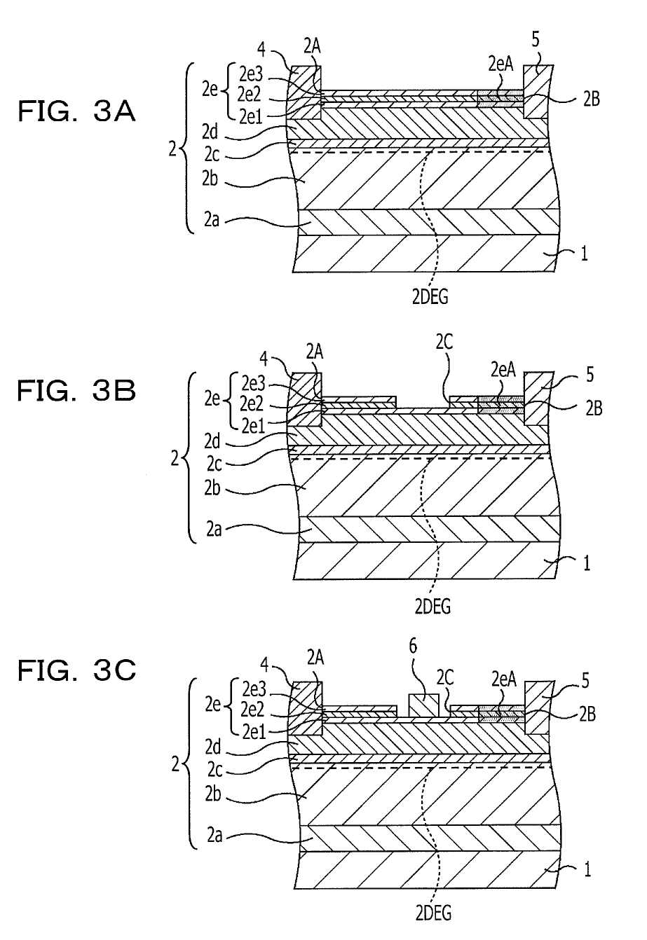

As illustrated in FIG. 3A, the source electrode 4 and the drain electrode 5 are formed. A photoresist mask for forming the source electrode 4 and the drain electrode 5 is formed. For example, a two-layer resist, which has a visor structure and is suitable for a vapor deposition process and a lift-off process, is used to form the photoresist mask. The photoresist is applied to the compound semiconductor multilayer structure 2 and openings that expose the electrode recesses 2A and 2B are formed in the photoresist. A photoresist mask is formed so as to have the openings. An electrode material, for example titanium and aluminium, is deposited over the photoresist mask, which has openings that expose the electrode recesses 2A and 2B, by the vapor deposition process. A layer of Ti may have a thickness of about 10 nm. A layer of Al may have a thickness of about 300 nm. The photoresist mask and titanium and aluminium deposited thereon are removed by the lift-off process. The SiC substrate 1 is heat-treated at a temperature of about 400° C. to 1,000° C., for example about 600° C., in a nitrogen atmosphere, and then remaining titanium and aluminium makes ohmic contact with the electron supply layer 2d. When ohmic contact between the titanium and aluminium and the electron supply layer 2d is obtained, heat treatment may be omitted. The electrode recesses 2A and 2B are filled with portions of the electrode material, whereby the source electrode 4 and the drain electrode 5 are formed.

As illustrated in FIG. 3B, an electrode recess 2C for the gate electrode 6 is formed in the compound semiconductor multilayer structure 2. A photoresist is applied to a surface of the compound semiconductor multilayer structure 2. The photoresist is processed by lithography, and then an opening is formed in the photoresist so that a surface portion of the compound semiconductor multilayer structure 2 that corresponds to a planned site (planned electrode site) for the gate electrode 6 is exposed through the opening. A photoresist mask having the opening is formed.

Using the photoresist mask, portions of a planned electrode site of the capping layer 2e, for example a portion of the n-GaN sub-layer 2e3 and a portion of the AlN sub-layer 2e2, are removed by dry etching. The capping layer 2e is etched so that a surface of the n-GaN sub-layer 2e1 is exposed, and the electrode recess 2C is formed. For etching conditions, an inert gas such as argon and a chlorine-based gas such as Cl₂ are used as etching gases. For example, the flow rate of Cl₂ may be 30 sccm, the pressure thereof may be 2 Pa, and the input RF power may be 20 W. The photoresist mask is removed by ashing or the like.

As illustrated in FIG. 3C, the gate electrode 6 is formed. A photoresist mask for forming the gate electrode 6 is formed. For example, a two-layer resist that has a visor structure and is suitable for a vapor deposition process and a lift-off process is used to form the photoresist mask. The photoresist is applied to the compound semiconductor multilayer structure 2 and an opening that exposes the electrode recess 3C in the n-GaN sub-layer 2e1 is formed therein. The photoresist mask is formed so as to have the opening.

An electrode material, for example nickel and gold, is deposited by, for example, the vapor deposition process over the photoresist mask, which has the opening that exposes the electrode recess 2C. A layer of nickel may have a thickness of about 30 nm. A layer of gold may have a thickness of about 400 nm. The photoresist mask and the nickel and gold deposited thereon are removed by the lift-off process. The electrode recess 2C is filled with a portion of the electrode material, whereby the gate electrode 6 is formed so as to be in Schottky contact with the n-GaN sub-layer 2e1.

A Schottky-type AlGaN/GaN HEMT is formed through processes such as forming wiring lines that are coupled to the source electrode 4, the drain electrode 5, and the gate electrode 6.

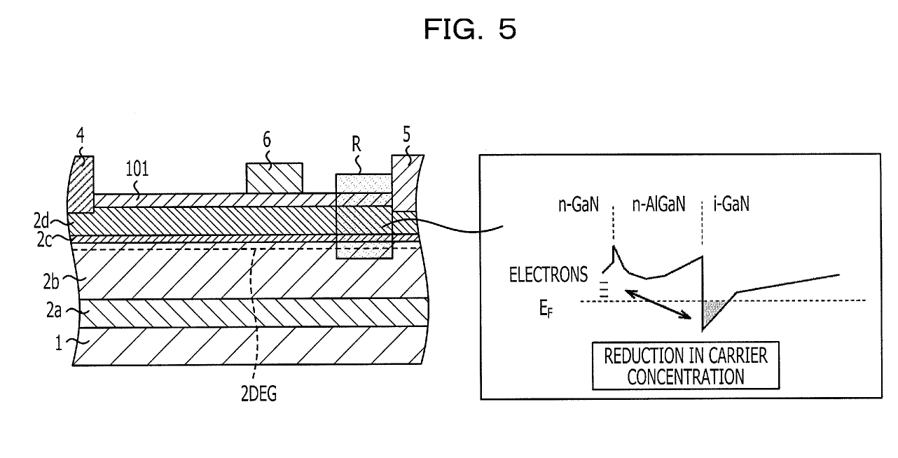

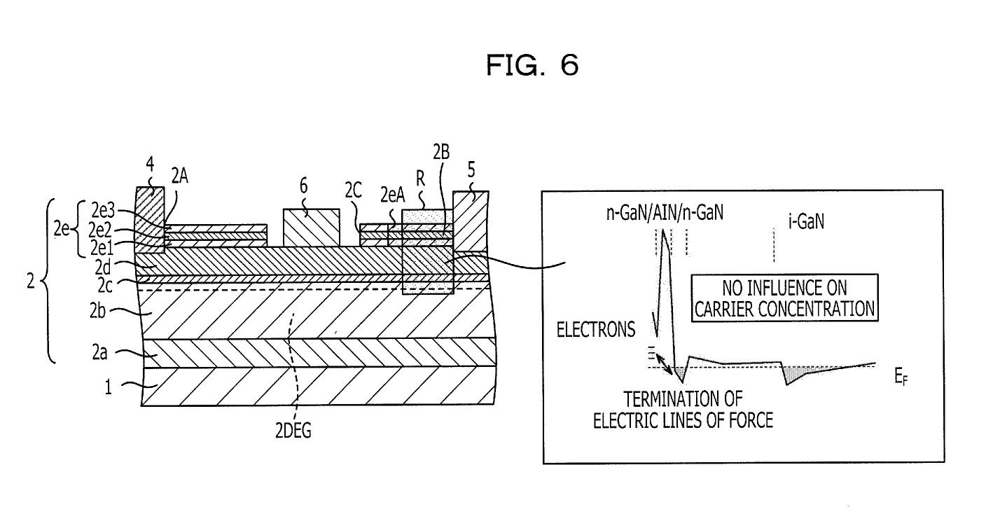

FIGS. 5 and 6 each illustrates an exemplary band diagram. The band diagram illustrated in each of FIGS. 5 and 6 may be a band diagram of a portion of a channel that is close to a drain electrode of an AlGaN/GaN HEMT. In each of FIGS. 5 and 6, the portion close to the drain electrode is a rectangular region represented by R. In FIG. 5, members that are the same as those of the compound semiconductor device illustrated in FIG. 1 to FIG. 4 are denoted by the same reference numerals as those used above.

In the AlGaN/GaN HEMT illustrated in FIG. 5, a capping layer 101 which has a thickness of about 5 nm and which is made of n-GaN is formed on an electron supply layer 2d. In the AlGaN/GaN HEMT illustrated in FIG. 5, electrons are trapped on a surface portion of the capping layer 101 that is close to a drain electrode 5 because of an intense electric field generated by applying a high drain voltage to the drain electrode 5. The concentration of an n-type impurity in the capping layer 101 is about 2×10¹⁸ cm⁻³, and the carrier concentration thereof is less than the carrier concentration of an electron supply layer 2d. Therefore, the trapped electrons cause current collapse. The concentration of carriers generated in an electron transit layer 2b, for example, the concentration of a 2DEG, is reduced, whereby the on-resistance of the AlGaN/GaN HEMT is increased.

In the AlGaN/GaN HEMT illustrated in FIG. 6, a capping layer 2e having a three-layer structure is formed on an electron supply layer 2d. Therefore, although the energy level of an n-GaN sub-layer 2e1 is low in relation to an AlN sub-layer 2e2, the energy level may be higher than the Fermi energy Ef.

In addition to the capping layer 2e, which has such a three-layer structure, a high-concentration n-type site 2eA is formed in a portion of the capping layer 2e that is close to a drain electrode 5, for example a region that is located between a gate electrode 6 and the drain electrode 5 and is next to the drain electrode 5. The capping layer 2e includes n-GaN sub-layers 2e1 and 2e3 and an AlN sub-layer 2e2 sandwiched therebetween. When forming the high-concentration n-type site 2eA by annealing the capping layer 2e during the formation of the AlN sub-layer 2e2, the damage to the electron supply layer 2d and the like by annealing is reduced and therefore good surface morphology may be obtained. The high-concentration n-type site 2eA has a carrier concentration higher than the carrier concentration of the electron supply layer 2d and an energy level lower than the Fermi energy Ef. Therefore, electric lines of force emanating from electrons trapped on a surface of the high-concentration n-type site 2eA terminate with the high-concentration n-type site 2eA. The influence of the electrons that are trapped on the high-concentration n-type site 2eA on the electron supply layer 2d is reduced and the reduction in concentration of a 2DEG generated in the electron supply layer 2d is suppressed.

a highly-reliable and high-voltage Schottky-type AlGaN/GaN HEMT with a relatively simple configuration in which the occurrence of current collapse and the deterioration of device properties are reduced is provided.

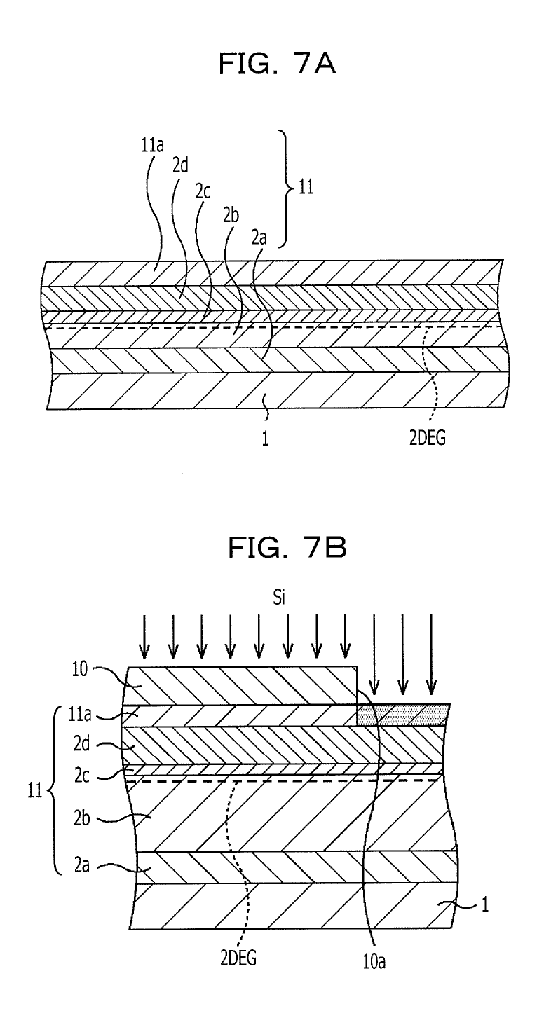

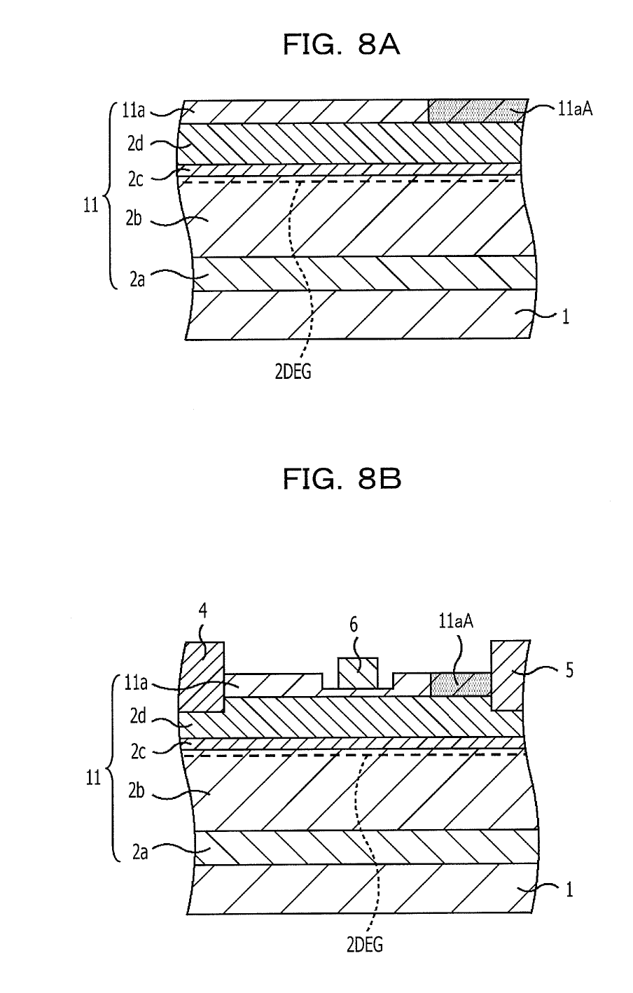

FIGS. 7A, 7B, 8A, and 8B illustrate an exemplary method for manufacturing a compound semiconductor device. The compound semiconductor device may be, for example, a Schottky-type AlGaN/GaN HEMT. A high-concentration n-type site is locally formed in a given region of a capping layer with a n-GaN monolayer.

As illustrated in FIG. 7A, a compound semiconductor multilayer structure 11 is formed on a SiC substrate 1. The compound semiconductor multilayer structure 11, as well as the compound semiconductor multilayer structure 2 illustrated in FIGS. 1A to 2C, is formed so that a buffer layer 2a, an electron transit layer 2b, an intermediate layer 2c, and an electron supply layer 2d are formed in that order. A capping layer 11a is formed on the electron supply layer 2d instead of the above-mentioned capping layer 2e. A capping layer 11a is formed as the capping layer 11a under substantially the same conditions as those used to grow the n-GaN sub-layers 2e1 and 2e3 of the capping layer 2e so as to have a thickness of about 5 nm and contain silicon at a concentration of about 2×10¹⁸ cm⁻³.

A process illustrated in FIGS. 1B and 1C are performed. A photoresist mask 10 having an opening 10a is formed on the capping layer 11a.

As illustrated in FIG. 7B, the capping layer 11a is doped with an n-type impurity. Using the photoresist mask 10, the n-type impurity is, for example, silicon is implanted into a surface portion of the capping layer 11a that is exposed through the opening 10a at a dose of about 5×10¹² cm⁻² to 1×10¹⁶ cm⁻², for example about 1×10¹³ cm⁻², with an acceleration energy where a peak of concentration distribution is located in a lower portion (a portion extending from the interface between the capping layer 11a and the electron supply layer 2d to a given thickness) of the capping layer 11a. The implanted n-type impurity may be germanium, oxygen, or the like. When the dose of the n-type impurity is less than about 5×10¹² cm⁻², a carrier concentration higher than the carrier concentration of the electron supply layer 2d may not be obtained. When the dose of the n-type impurity is more than about 1×10¹⁶ cm⁻², crystal defects are caused by damage due to ion implantation and current collapse may be worsened. Therefore, when setting the dose of the n-type impurity to about 5×10¹² cm⁻² to 1×10¹⁶ cm⁻², the occurrence of crystal defects is reduced and a carrier concentration higher than the carrier concentration of the electron supply layer 2d may be obtained.

As illustrated in FIG. 8A, a high-concentration n-type site 11aA is formed in the capping layer 11a. The photoresist mask 10 is removed by ashing or wet etching using a given chemical solution. The capping layer 11a is annealed. Therefore, after silicon implanted in the capping layer 11a is activated, the high-concentration n-type site 11aA is locally formed in the capping layer 11a. The high-concentration n-type site 11aA has a carrier concentration higher than the carrier concentration of the electron supply layer 2d and an energy level lower than the Fermi energy.

As illustrated in FIGS. 1A to 3C, an implantation mask for silicon may be formed on the capping layer 11a and the n-type impurity may be ion-implanted into the capping layer 11a using the implantation mask and the photoresist mask 10.

After process illustrated in FIGS. 2C to 3C are performed, a device illustrated in FIG. 8B is obtained. After wiring lines are formed so as to be coupled to a source electrode 4, a drain electrode 5, and a gate electrode 6, a Schottky-type AlGaN/GaN HEMT is formed.

The high-concentration n-type site 11aA is formed in a portion (a portion next to the drain electrode 5) of the capping layer 11a that is close to the drain electrode 5. The high-concentration n-type site 11aA has a carrier concentration higher than the carrier concentration of the electron supply layer 2d and an energy level lower than the Fermi energy. Therefore, electric lines of force emanating from electrons trapped on a surface of the high-concentration n-type site 11aA terminate with the high-concentration n-type site 11aA. The influence of the electrons trapped on the high-concentration n-type site 11aA is blocked and the influence thereof on the electron supply layer 2d is reduced; hence, the reduction in concentration of a 2DEG generated in the electron supply layer 2d is alleviated.

A highly-reliable and high-voltage Schottky-type AlGaN/GaN HEMT with a relatively simple configuration in which the occurrence of current collapse and the deterioration of device properties are reduced is provided.

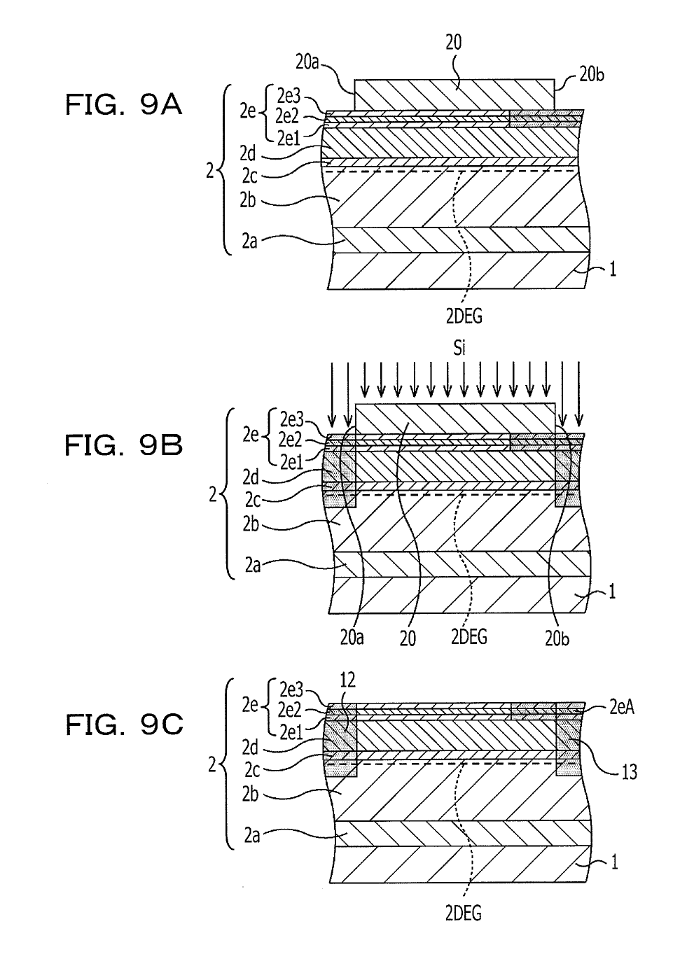

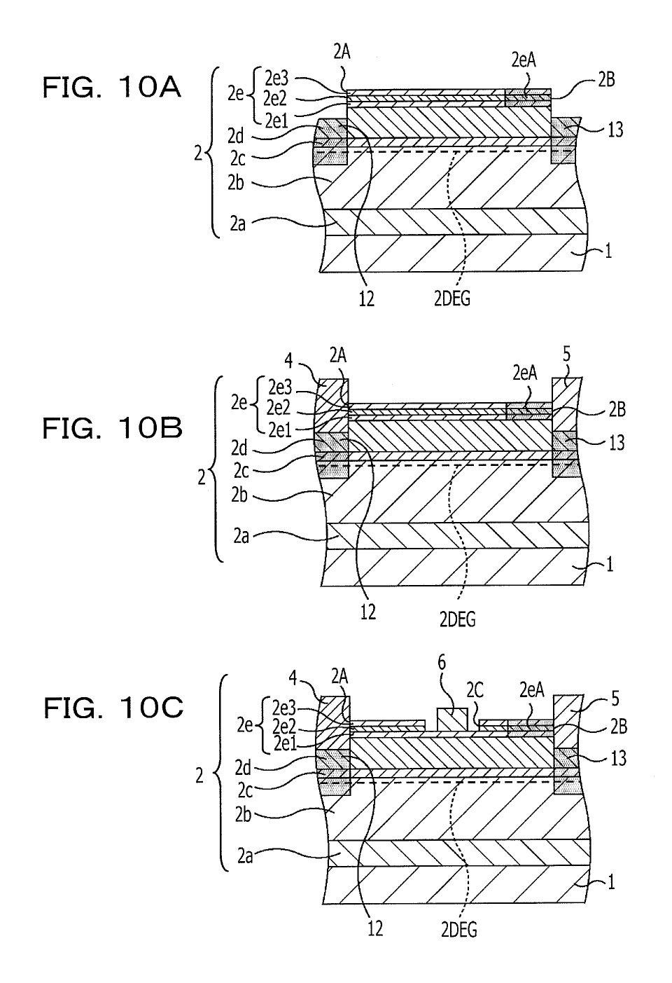

FIGS. 9A to 9C and 10A to 10C illustrate an exemplary method for manufacturing a compound semiconductor device. The compound semiconductor device may be, for example, a Schottky-type AlGaN/GaN HEMT. High-concentration n-type sites are formed under a source electrode and a drain electrode.

The processes illustrated in FIGS. 1A to 2A are performed. A photoresist mask 10 illustrated in FIG. 9A is removed by ashing or wet etching using a given chemical solution.

As illustrated in FIG. 9A, a photoresist mask 20 is formed. After a photoresist is applied to a capping layer 2e of a compound semiconductor multilayer structure 2, through irradiation with ultraviolet light portions of the photoresist that correspond to a planned site for a source electrode 4 and a planned site for a drain electrode 5 are opened. The photoresist mask 20 is formed on the capping layer 2e so as to have an opening 20a that exposes the planned site for the source electrode 4 and an opening 20b that exposes the planned site for the drain electrode 5.EDITOR: added text Through the opening 20a, a portion of the capping layer 2e that corresponds to the planned site of the source electrode 4 is exposed. Through the opening 20b, a portion (Si-doped portion) of the capping layer 2e that corresponds to the planned site for the drain electrode 5 is exposed.

As illustrated in FIG. 9B, the planned sites for the source electrode 4 and the drain electrode 5 of the compound semiconductor multilayer structure 2 are doped with an n-type impurity. Using the photoresist mask 20, the n-type impurity is ion-implanted into a surface portion of the capping layer 2e that is exposed through the opening 20a and a surface portion (Si-doped portion) of the capping layer 2e that is exposed through the opening 20b. The n-type impurity is, for example, silicon and is implanted at a dose of about 5×10¹⁴ cm⁻² to 1×10¹⁶ cm⁻¹, for example about 1×10¹⁵ cm⁻², with an acceleration energy so that a peak of concentration distribution is located near a surface of the an electron supply layer 2d. The implanted n-type impurity may be germanium, oxygen, or the like instead of silicon. A peak of the concentration distribution of the n-type impurity may be formed at each of the interface between the source electrode 4 and the compound semiconductor multilayer structure 2, and the interface between the drain electrode 5 and the compound semiconductor multilayer structure 2. A of the concentration distribution of the n-type impurity may be formed near a surface portion of the electron supply layer 2d that is located on the bottom surfaces of the source electrode 4 and the drain electrode 5. When the dose of the n-type impurity is less than about 5×10¹⁴ cm⁻², the contact resistances of the source electrode 4 and the drain electrode 5 may not be reduced. When the dose of the n-type impurity is more than about 1×10¹⁶ cm⁻², crystal defects are caused by damage due to ion implantation and therefore device properties may be deteriorated. When the dose of the n-type impurity is set to about 5×10¹⁴ cm⁻² to 1×10¹⁶ cm⁻², the occurrence of crystal defects is reduced and the contact resistances of the source electrode 4 and the drain electrode 5 may be reduced.

As illustrated in FIG. 9C, high-concentration n-type sites 2eA, 12, and 13 are formed in the capping layer 2e. The photoresist mask 20 is removed by ashing or wet etching using a given chemical solution. The capping layer 2e is annealed. After the n-type impurity (herein, silicon) that is implanted in the capping layer 2e is activated, The high-concentration n-type sites 2eA, 12, and 13 are locally formed in the capping layer 2e.

The high-concentration n-type site 2eA has a carrier concentration higher than the carrier concentration of the electron supply layer 2d and an energy level lower than the Fermi energy. In the high-concentration n-type sites 12 and 13, the contact resistances of the source electrode 4 and the drain electrode 5 are reduced due to a high concentration of the n-type impurity. Since the high-concentration n-type sites 2eA, 12, and 13 are formed through one process of annealing, the number of steps is not increased and the damage to the compound semiconductor multilayer structure 2 may be reduced.

As illustrated in FIGS. 1A to 3C, an implantation mask for silicon may be formed on the capping layer 2e and the n-type impurity may be ion-implanted into the capping layer 2e using the implantation mask, the photoresist mask 10, and the photoresist mask 20.

As illustrated in FIG. 10A, an electrode recess 2A and an electrode recess 2B are formed in the planned site for the source electrode 4 and the planned site for the drain electrode 5, respectively, with the planned sites being located on a surface of the compound semiconductor multilayer structure 2. That is, a photoresist is applied to the surface of the compound semiconductor multilayer structure 2. After the photoresist is processed by lithography, openings are formed in the photoresist so that surface portions of the compound semiconductor multilayer structure 2 that correspond to the planned sites (planned electrode sites) for the source electrode 4 and the drain electrode 5 are exposed through the openings. A photoresist mask having the openings is formed.

Using the photoresist mask, planned electrode sites of the capping layer 2e and the electron supply layer 2d are removed by dry etching until surface portions of the electron supply layer 2d are removed. A overlapping portion of the high-concentration n-type sites 2eA and 13 in the capping layer 2e is removed by dry etching. The result is that the electrode recesses 2A and 2B are formed such that the planned electrode sites of the electron supply layer 2d are exposed. For etching conditions, an inert gas such as argon and a chlorine-based gas such as Cl₂ may be used as etching gases. For example, the flow rate of Cl₂ may be set to 30 sccm, the pressure thereof may be set to 2 Pa, and the input RF power may be set to 20 W.

The electrode recesses 2A and 2B may be formed in so that the capping layer 2e is etched until intermediate portions thereof are exposed or surface portions of the electron supply layer 2d are exposed. Ion implantation may be performed as illustrated in FIG. 9B so that a peak of the concentration distribution of the n-type impurity is located on a surface exposed by dry etching. The photoresist mask is removed by ashing or the like.

The photoresist mask 20 for ion implantation and the photoresist mask used to form the electrode recesses 2A and 2B may be separately formed. The photoresist mask used to form the electrode recesses 2A and 2B may be omitted. The photoresist mask 20 is not removed after ion implantation but is removed after the photoresist mask 20 is used to form the electrode recesses 2A and 2B.

The source electrode 4 and the drain electrode 5 are formed as illustrated in FIG. 10B. A photoresist mask for forming the source electrode 4 and the drain electrode 5 is formed. For example, a two-layer resist that has a visor structure and is suitable for a vapor deposition process and a lift-off process may be used to form the photoresist mask. The photoresist is applied to the compound semiconductor multilayer structure 2 and then openings that expose the electrode recesses 2A and 2B are formed therein. The photoresist mask is formed so as to have the openings. An electrode material, for example titanium and aluminium, is deposited over the photoresist mask, which has the openings that expose the electrode recesses 2A and 2B, by the vapor deposition process. A layer of Ti may have a thickness of about 10 nm. A layer of Al may have a thickness of about 300 nm. The photoresist mask and titanium and aluminium deposited thereon are removed by the lift-off process. After a SiC substrate 1 is heat-treated at a temperature of about 400° C. to 1,000° C., for example about 600° C., in a nitrogen atmosphere, the remaining titanium and aluminium makes ohmic contact with the electron supply layer 2d. When ohmic contact between the titanium and aluminium and the electron supply layer 2d is obtained, heat treatment may be omitted. The electrode recesses 2A and 2B are filled with portions of the electrode material, whereby the source electrode 4 and the drain electrode 5 are formed.

The high-concentration n-type site 12 is formed under the source electrode 4 so that the high-concentration n-type site 12 is in contact with the source electrode 4 and a peak of the concentration of the n-type impurity is located at a contact therebetween. The high-concentration n-type site 13 is formed under the drain electrode 5 so that the high-concentration n-type site 13 is in contact with the drain electrode 5 and a peak of the concentration of the s-type impurity is located at a contact therebetween. The contact resistance of the source electrode 4 and the drain electrode 5 may be reduced due to the high-concentration n-type sites 12 and 13.

After performing processes illustrated in FIGS. 3B and 3C, a device illustrated in FIG. 10C may be obtained. After wiring lines are formed so as to be coupled to the source electrode 4, the drain electrode 5, and the gate electrode 6, a Schottky-type AlGaN/GaN HEMT is formed.

The high-concentration n-type site 2eA is formed in a portion (a portion next to the drain electrode 5) of the capping layer 2e that is close to the drain electrode 5. The high-concentration n-type site 12 is formed under the source electrode 4 so as to be in contact with the high-concentration n-type site 2eA. The high-concentration n-type site 13 is formed under the drain electrode 5 so as to be in contact with the high-concentration n-type site 12. The high-concentration n-type site 2eA has a carrier concentration higher than the carrier concentration of the electron supply layer 2d and an energy level lower than the Fermi energy. Thus, electric lines of force emanating from electrons trapped on a surface of the high-concentration n-type site 2eA terminate with the high-concentration n-type site 2eA. Therefore, the influence of the electrons trapped on the high-concentration n-type site 2eA is blocked and the influence of the trapped electrons on the electron supply layer 2d is reduced; hence, reduction in concentration of a 2DEG generated in the electron supply layer 2d is reduced. The bottom surface of the source electrode 4 and the bottom surface of the drain electrode 5 are in contact with the high-concentration n-type sites 12 and 13, respectively; hence, the contact resistances of the source electrode 4 and the drain electrode 5 may be reduced.

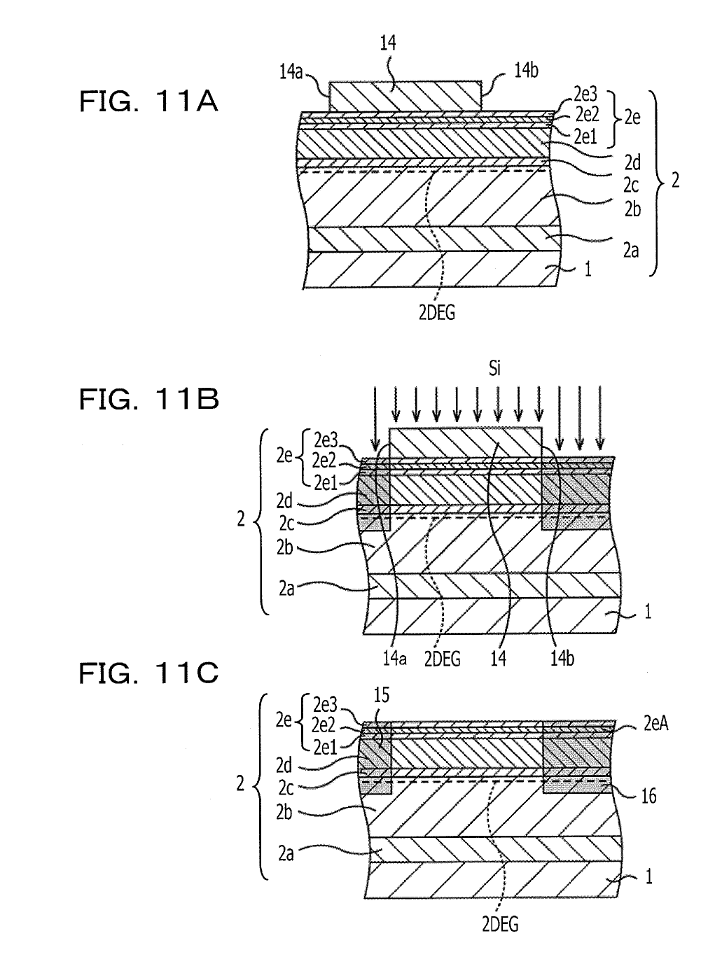

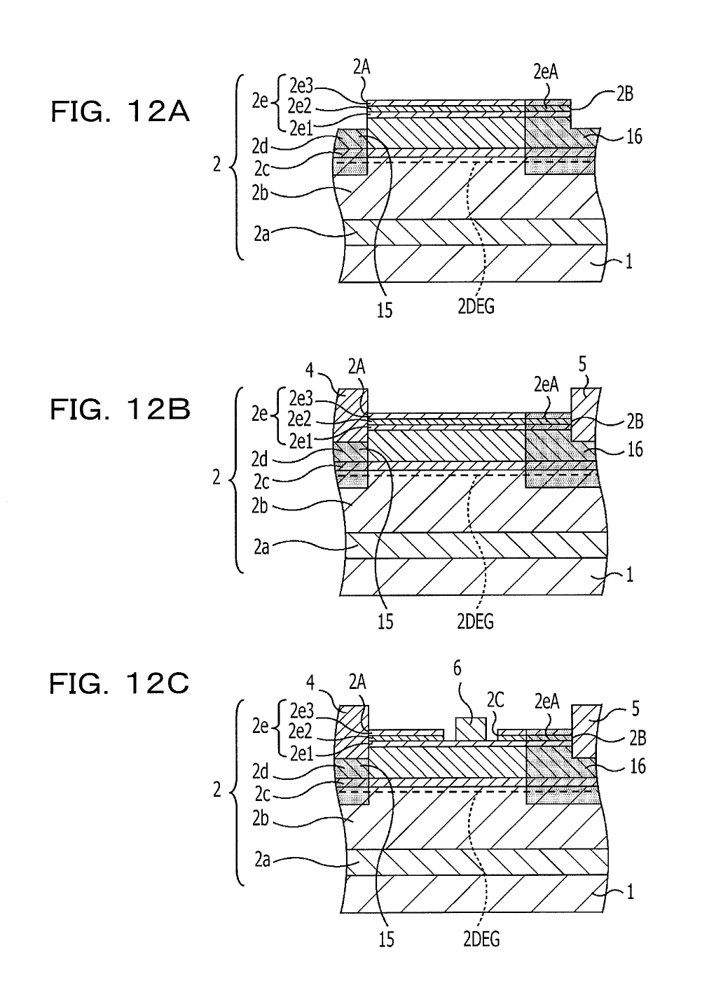

The number of processes is not increased, the occurrence of current collapse is reduced with a relatively simple configuration, and the contact resistances of the source electrode 4 and the drain electrode 5 are reduced. A highly-reliable and high-voltage Schottky-type AlGaN/GaN HEMT in which the deterioration of device properties is reduced is provided. FIGS. 11A to 11C and 12A to 12C illustrate an exemplary method for manufacturing a compound semiconductor device. The compound semiconductor device may be, for example, a Schottky-type AlGaN/GaN HEMT. High-concentration n-type sites are formed under a source electrode and a drain electrode.

Processes illustrated in FIGS. 1A and 1B are performed. As illustrated in FIG. 11A, a photoresist mask 14 is formed. After a photoresist is applied to a capping layer 2e of a compound semiconductor multilayer structure 2, through irradiation with ultraviolet light a given portion of the photoresist that includes a planned site for a drain electrode 5 is openedremoved. The photoresist mask 14 is formed on the capping layer 2e so as to have an opening 14a that exposes a planned site for a source electrode 4 and an opening 14b that exposes the given portion, which includes the planned site for the drain electrode 5.EDITOR: added text In the opening 14a, a portion of the capping layer 2e that corresponds to the planned site for the source electrode 4 is exposed. In the opening 14b, a surface portion of the capping layer 2e that includes the planned site for the drain electrode 5 and a range extending about 1 μm from an end thereof toward a planned site for a gate electrode 6 is exposed.

As illustrated in FIG. 11B, the capping layer 2e of the compound semiconductor multilayer structure 2 is doped with an n-type impurity. Using the photoresist mask 20, the n-type impurity is ion-implanted into a surface portion of the capping layer 2e that is exposed through the opening 14a and a surface portion (Si-doped portion) of the capping layer 2e that is exposed through the opening 14b. The n-type impurity is, for example, silicon and is implanted at a dose of about 5×10¹⁴ cm⁻² to 1×10¹⁶ cm⁻, for example about 1×10¹⁵ cm⁻², with an acceleration energy so that a peak of concentration distribution is located near a surface of the an electron supply layer 2d. The implanted n-type impurity may be germanium, oxygen, or the like instead of silicon. A peak of the concentration distribution of the n-type impurity may be formed at both the interface between the source electrode 4 and the compound semiconductor multilayer structure 2 and the interface between the drain electrode 5 and the compound semiconductor multilayer structure 2. A peak of the concentration distribution of the n-type impurity may be formed near a surface portion of the electron supply layer 2d that is located on the bottom surfaces of the source electrode 4 and the drain electrode 5.

When the dose of the n-type impurity is less than about 5×10¹² cm⁻², a carrier concentration higher than the carrier concentration of the electron supply layer 2d may not be obtained. When the dose of the n-type impurity is more than about 1×10¹⁶ cm⁻², crystal defects are caused by damage due to ion implantation and therefore current collapse may be worsened. When the dose of the n-type impurity is less than about 5×10¹⁴ cm⁻², the contact resistances of the source electrode 4 and the drain electrode 5 may not be reduced. When the dose of the n-type impurity is more than about 1×10¹⁶ cm⁻², crystal defects are caused by damage due to ion implantation and therefore device properties may be deteriorated. When setting the dose of the n-type impurity to about 5×10¹⁴ cm⁻² to 1×10¹⁶ cm⁻², crystal defects are reduced and a carrier concentration higher than the carrier concentration of the electron supply layer 2d is obtained. The contact resistances of the source electrode 4 and the drain electrode 5 may be reduced.EDITOR: added text

As illustrated in FIG. 11C, high-concentration n-type sites 2eA, 15, and 16 are formed in the capping layer 2e. The photoresist mask 14 is removed by ashing or wet etching using a given chemical solution. The capping layer 2e is annealed. The n-type impurity (herein, silicon) implanted in the capping layer 2e is activated, with the result that the high-concentration n-type sites 2eA, 15, and 16 are locally formed in the capping layer 2e.

The high-concentration n-type site 2eA has a carrier concentration higher than the carrier concentration of the electron supply layer 2d and an energy level lower than the Fermi energy. In the high-concentration n-type sites 15 and 16, the contact resistances of the source electrode 4 and the drain electrode 5 are sufficiently reduced to a high concentration of the n-type impurity. The high-concentration n-type sites 2eA, 12, and 13 may be formed through one process of ion implantation and one process of annealing. Since the compound semiconductor multilayer structure 2 is formed through a relatively small number of processes, the damage to the compound semiconductor multilayer structure 2 may be reduced.

As illustrated in FIGS. 1A to 3C, an implantation mask for silicon may be formed on the capping layer 2e and the n-type impurity may be ion-implanted into the capping layer 2e using the implantation mask and the photoresist mask 14.

As illustrated in FIG. 12A, an electrode recess 2A and an electrode recess 2B are formed in the planned site for the source electrode 4 and the planned site for the drain electrode 5, respectively, with the planned sites being located on a surface of the compound semiconductor multilayer structure 2. A photoresist is applied to the surface of the compound semiconductor multilayer structure 2. The photoresist is processed by lithography, whereby openings are formed in the photoresist so that surface portions of the compound semiconductor multilayer structure 2 that correspond to the planned sites (planned electrode sites) for the source electrode 4 and the drain electrode 5 are exposed through the openings. A photoresist mask having the openings is formed.

Using the photoresist mask, planned electrode sites of the capping layer 2e and the electron supply layer 2d are removed by dry etching until a surface portion of the electron supply layer 2d are removed. The electrode recesses 2A and 2B are formed so that the planned electrode sites of the electron supply layer 2d are exposed. For etching conditions, an inert gas such as argon and a chlorine-based gas such as Cl₂ may be used as etching gases. For example, the flow rate of Cl₂ may be set to 30 sccm, the pressure thereof may be set to 2 Pa, and the input RF power may be set to 20 W.

The electrode recesses 2A and 2B may be formed so that the capping layer 2e is etched until intermediate portions thereof are exposed or surface portions of the electron supply layer 2d are exposed. Ion implantation may be performed as illustrated in FIG. 9B so that a peak of the concentration distribution of the n-type impurity is located on a surface that is exposed by dry etching. The photoresist mask is removed by ashing or the like.

The source electrode 4 and the drain electrode 5 are formed as illustrated in FIG. 12B. A photoresist mask for forming the source electrode 4 and the drain electrode 5 is formed. For example, a two-layer resist that has a visor structure and is suitable for a vapor deposition process and a lift-off process may be used to form the photoresist mask. The photoresist is applied to the compound semiconductor multilayer structure 2 and openings that expose the electrode recesses 2A and 2B are formed therein. The photoresist mask is formed so as to have the openings. An electrode material, for example titanium and aluminium, is deposited over the photoresist mask, which has openings that expose the electrode recesses 2A and 2B, by the vapor deposition process or the like. A layer of titanium may have a thickness of about 10 nm. A layer of aluminium may have a thickness of about 300 nm. The photoresist mask and titanium and aluminium deposited thereon are removed by the lift-off process. After a SiC substrate 1 is heat-treated at a temperature of about 400° C. to 1,000° C., for example about 600° C., in a nitrogen atmosphere, the remaining titanium and aluminium make ohmic contact with the electron supply layer 2d. When ohmic contact between titanium and aluminium and the electron supply layer 2d is obtained, heat treatment may be omitted. The electrode recesses 2A and 2B are filled with portions of the electrode material, whereby the source electrode 4 and the drain electrode 5 are formed.

The high-concentration n-type site 15 is formed under the source electrode 4 so that the high-concentration n-type site 15 is in contact with the source electrode 4 and a peak of the concentration of the n-type impurity is located at a contact therebetween. The high-concentration n-type site 16 is formed under the drain electrode 5 such that the high-concentration n-type site 16 is in contact with the drain electrode 5 and a peak of the concentration of the n-type impurity is located at a contact therebetween. The contact resistances of the source electrode 4 and the drain electrode 5 may be reduced due to the high-concentration n-type sites 15 and 16.

After the processed illustrated in FIGS. 3B and 3C are performed, a device illustrated in FIG. 12C is obtained. After wiring lines are formed so as to be coupled to the source electrode 4, the drain electrode 5, and the gate electrode 6, a Schottky-type AlGaN/GaN HEMT is formed.

The high-concentration n-type site 2eA is formed in a portion (a portion next to the drain electrode 5) of the capping layer 2e that is close to the drain electrode 5. The high-concentration n-type site 15 is formed under the source electrode 4 and is in contact with the high-concentration n-type site 2eA. The high-concentration n-type site 16 is formed under the drain electrode 5 and is in contact with the high-concentration n-type site 15. The high-concentration n-type site 2eA has a carrier concentration higher than the carrier concentration of the electron supply layer 2d and an energy level lower than the Fermi energy. Therefore, electric lines of force emanating from electrons trapped on a surface of the high-concentration n-type site 2eA terminate with the high-concentration n-type site 2eA. The influence of the electrons trapped on the high-concentration n-type site 2eA is blocked, the influence thereof on the electron supply layer 2d is reduced and the reduction in concentration of a 2DEG generated in the electron supply layer 2d is reduced. The bottom surface of the source electrode 4 and the bottom surface of the drain electrode 5 are in contact with the high-concentration n-type sites 15 and 16, respectively; hence, the contact resistances of the source electrode 4 and the drain electrode 5 may be reduced.

A highly-reliable and high-voltage Schottky-type AlGaN/GaN HEMT with a relatively simple configuration in which the occurrence of current collapse, the occurrence of current collapse and the deterioration of device properties are reduced is provided.

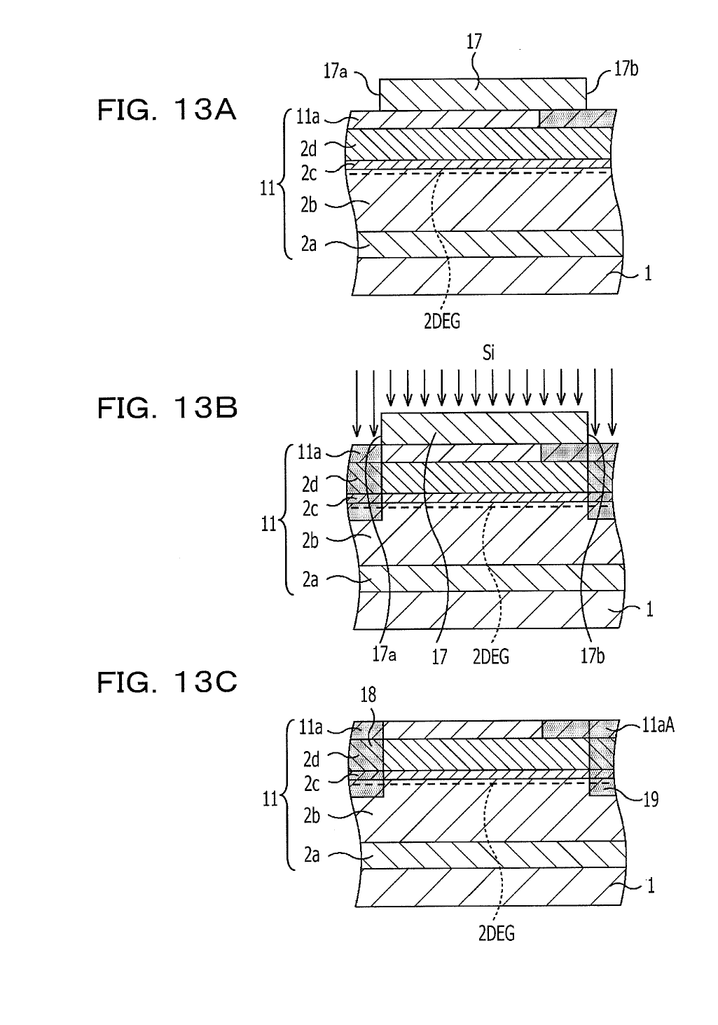

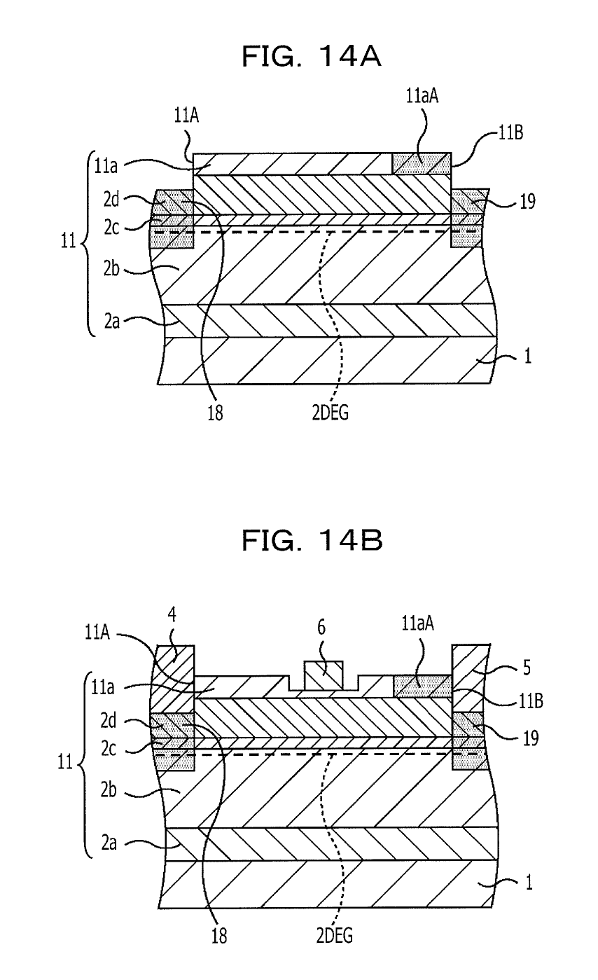

FIGS. 13A to 13C, 14A, and 14B illustrate an exemplary method for manufacturing a compound semiconductor device. The compound semiconductor device may be, for example, a Schottky-type AlGaN/GaN HEMT. High-concentration n-type sites are formed under a source electrode and a drain electrode.

After processes illustrated in FIGS. 7A and 7B are performed, an isolated compound semiconductor multilayer structure 11 is formed. A photoresist mask 10 illustrated in FIG. 7B is removed by ashing or wet etching using a given chemical solution.

As illustrated in FIG. 13A, a photoresist mask 17 is formed. After a photoresist is applied to a capping layer 11a of the compound semiconductor multilayer structure 11, through irradiation with ultraviolet light, portions of the photoresist that correspond to a planned site for a source electrode 4 and a planned site for a drain electrode 5 are opened. The photoresist mask 17 is formed on the capping layer 11a so as to have an opening 17a that exposes the planned site for the source electrode 4 and an opening 17b that exposes the planned site for the drain electrode 5. In the opening 17a, a portion of the capping layer 11a that corresponds to the planned site of the source electrode 4 is exposed. In the opening 17b, a portion (Si-doped portion) of the capping layer 11a that corresponds to the planned site for the drain electrode 5 is exposed.

As illustrated in FIG. 13B, the planned sites for the source electrode 4 and the drain electrode 5 of the compound semiconductor multilayer structure 11 are doped with an n-type impurity. Using the photoresist mask 17, the n-type impurity is ion-implanted into a surface portion of the capping layer 11a that is exposed through the opening 17a and a surface portion (Si-doped portion) of the capping layer 11a that is exposed through the opening 17b. The n-type impurity is, for example, silicon and is implanted at a dose of about 5×10¹⁴ cm⁻² to 1×10¹⁶ cm⁻², for example about 1×10¹⁵ cm⁻², with an acceleration energy so that a peak of concentration distribution is located near a surface of the electron supply layer 2d. The implanted n-type impurity may be germanium, oxygen, or the like instead of silicon. A peak of the concentration distribution of the n-type impurity may be formed at both the interface between the source electrode 4 and the compound semiconductor multilayer structure 11, and the interface between the drain electrode 5 and the compound semiconductor multilayer structure 11. A peak of the concentration distribution of the n-type impurity may be formed near a surface portion of the electron supply layer 2d that is located on the bottom surfaces of the source electrode 4 and the drain electrode 5. When the dose of the n-type impurity is less than about 5×10¹⁴ cm⁻², the contact resistances of the source electrode 4 and the drain electrode 5 may possibly not be reduced. When the dose of the n-type impurity is more than about 1×10¹⁶ cm⁻², crystal defects are caused by damage due to ion implantation and device properties may be deteriorated. When the dose of the n-type impurity is set to about 5×10¹⁴ cm⁻² to 1×10¹⁶ cm⁻², the occurrence of crystal defects is reduced and the contact resistances of the source electrode 4 and the drain electrode 5 may be reduced.

As illustrated in FIG. 13C, high-concentration n-type sites 11aA, 18, and 19 are formed in the capping layer 11a. The photoresist mask 17 is removed by ashing or wet etching using a given chemical solution. After the capping layer 11a is annealed, the n-type impurity (herein, silicon) implanted in the capping layer 11a is activated. The high-concentration n-type sites 11aA, 18, and 19 are locally formed in the capping layer 11a.

The high-concentration n-type site 11aA has a carrier concentration higher than the carrier concentration of the electron supply layer 2d and an energy level lower than the Fermi energy. In the high-concentration n-type sites 18 and 19, the contact resistances of the source electrode 4 and the drain electrode 5 is reduced due to the n-type impurity. Since the high-concentration n-type sites 11aA, 18, and 19 are formed through one process of annealing, the number of processes is not increased and the damage to the compound semiconductor multilayer structure 11 is reduced.

As illustrated in FIGS. 1A to 3C, an implantation mask for silicon may be formed on the capping layer 11a and the n-type impurity may be ion-implanted into the capping layer 11a using the implantation mask, the photoresist mask 10, and the photoresist mask 17.

As illustrated in FIG. 14A, an electrode recess 11A and an electrode recess 11B are formed in the planned site for the source electrode 4 and the planned site for the drain electrode 5, respectively, with the planned sites being located on a surface of the compound semiconductor multilayer structure 11. A photoresist is applied to the surface of the compound semiconductor multilayer structure 11. After the photoresist is processed by lithography, openings are formed in the photoresist so that surface portions of the compound semiconductor multilayer structure 11 that correspond to the planned sites (planned electrode sites) for the source electrode 4 and the drain electrode 5 are exposed through the openings. A photoresist mask having the openings is formed.

Using the photoresist mask, planned electrode sites of the capping layer 11a and the electron supply layer 2d are removed by dry etching until surface portions of the electron supply layer 2d are removed. A overlapping portion of the high-concentration n-type sites 11aA and 19 in the capping layer 11a is removed by dry etching. The electrode recesses 11A and 11B that expose the planned electrode sites of the electron supply layer 2d are formed. For etching conditions, an inert gas such as argon and a chlorine-based gas such as Cl₂ may be used as etching gases. For example, the flow rate of Cl₂ may be set to 30 sccm, the pressure thereof may be set to 2 Pa, and the input RF power may be set to 20 W.

The electrode recesses 11A and 11B may be formed so that the capping layer 11a is etched until intermediate portions thereof are exposed or surface portions of the electron supply layer 2d are exposed. Ion implantation may be performed as illustrated in FIG. 13B so that a peak of the concentration distribution of the n-type impurity is located on a surface that is exposed by dry etching. The photoresist mask is removed by ashing or the like.

The photoresist mask 17 for ion implantation and the photoresist mask used to form the electrode recesses 11A and 11B may be separately formed. The photoresist mask used to form the electrode recesses may be omitted. In this case, the photoresist mask 17 is not removed after ion implantation but may be removed after the photoresist mask 17 is used to form the electrode recesses 11A and 11B.

After processes illustrated in FIGS. 3A to 3C are performed, a device illustrated in FIG. 14B is obtained. After wiring lines are formed so as to be coupled to the source electrode 4, the drain electrode 5, and the gate electrode 6, a Schottky-type AlGaN/GaN HEMT is formed.

The high-concentration n-type site 11aA is formed in a portion (a portion next to the drain electrode 5) of the capping layer 11a that is close to the drain electrode 5. The high-concentration n-type site 18 is formed under the source electrode 4 so that the high-concentration n-type site 18 is in contact with the source electrode 4 and a peak of the concentration of the n-type impurity is located at a contact therebetween. The high-concentration n-type site 19 is formed under the source electrode 5 so that the high-concentration n-type site 19 is in contact with the drain electrode 5 and a peak of the concentration of the n-type impurity is located at a contact therebetween. The high-concentration n-type site 11aA has a carrier concentration higher than the carrier concentration of the electron supply layer 2d and an energy level lower than the Fermi energy. Therefore, electric lines of force emanating from electrons trapped on a surface of the high-concentration n-type site 11aA terminate with the high-concentration n-type site 11aA. The influence of the electrons trapped on the high-concentration n-type site 11aA is blocked and the influence thereof on the electron supply layer 2d is reduced, and in addition, a reduction in concentration of a 2DEG generated in the electron supply layer 2d is reduced. The bottom surface of the source electrode 4 and the bottom surface of the drain electrode 5 are in contact with the high-concentration n-type sites 18 and 19, respectively; therefore, the contact resistances of the source electrode 4 and the drain electrode 5 may be reduced.

The number of processes is not increased, the occurrence of current collapse is reduced with a relatively simple configuration, and the contact resistances of the source electrode 4 and the drain electrode 5 are reduced. A Schottky-type, highly-reliable, high-voltage AlGaN/GaN HEMT in which the deterioration of device properties is reduced is provided.

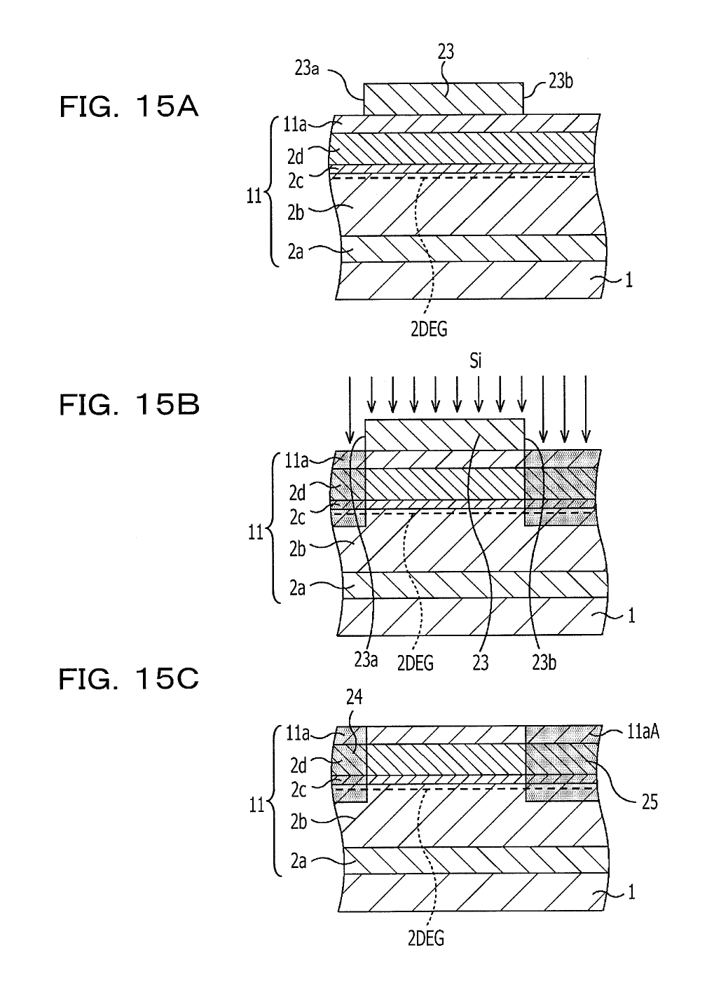

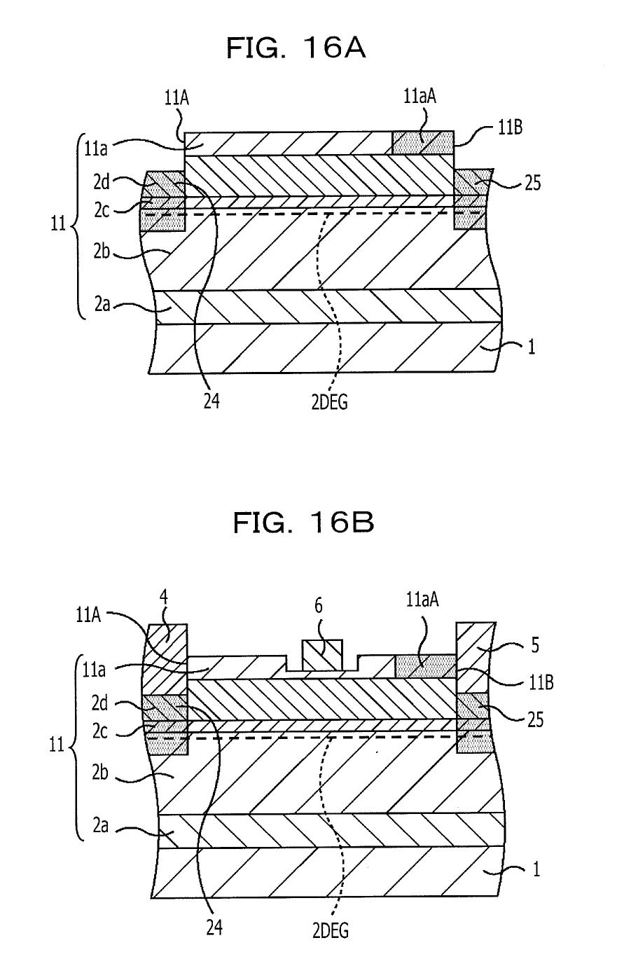

FIGS. 15A to 15C, 16A, and 16B illustrate an exemplary manufacturing method for a compound semiconductor device. The compound semiconductor device may be, for example, a Schottky-type AlGaN/GaN HEMT. A high-concentration n-type site is locally formed in a given region of a capping layer that has a monolayer structure. High-concentration n-type sites are also formed under a source electrode and a drain electrode.

After a process illustrated in FIG. 7A is performed, a compound semiconductor multilayer structure 11 is formed.

As illustrated in FIG. 15A, a photoresist mask 23 is formed. A photoresist is applied to a capping layer 11a of the compound semiconductor multilayer structure 11, and through irradiation with ultraviolet light a given portion of the photoresist that includes a planned site for a drain electrode 5 is opened. The photoresist mask 23 is formed on the capping layer 11a so as to have an opening 23a that exposes a planned site for a source electrode 4 and an opening 23b that exposes the planned site for the drain electrode 5. In the opening 23a, a portion of the capping layer 11a that corresponds to the planned site of the source electrode 4 is exposed. In the opening 23b, a surface portion of the capping layer 11a that includes the planned site for the drain electrode 5 and a range extending about 1 μm from an end thereof toward a gate electrode 6 is exposed.

As illustrated in FIG. 15B, the capping layer 11a of the compound semiconductor multilayer structure 11 is doped with an n-type impurity. The n-type impurity is ion-implanted into a surface portion of the capping layer 11a that is exposed through the opening 23a and a surface portion (Si-doped portion) of the capping layer 11a that is exposed through the opening 23b using the photoresist mask 23. The n-type impurity is, for example, silicon and is implanted at a dose of about 5×10¹⁴ cm⁻² to 1×10¹⁶ cm⁻², for example about 1×10¹⁵ cm⁻², with an acceleration energy so that a peak of concentration distribution is located near a surface of the an electron supply layer 2d. The implanted n-type impurity may be germanium, oxygen, or the like instead of silicon. A peak of the concentration distribution of the n-type impurity may be formed at the interface between the source electrode 4 and the compound semiconductor multilayer structure 11 as well as the interface between the drain electrode 5 and the compound semiconductor multilayer structure 11. A peak of the concentration distribution of the n-type impurity may be formed near a surface portion of the electron supply layer 2d that is located on the bottom surfaces of the source electrode 4 and the drain electrode 5.

When the dose of the n-type impurity is less than about 5×10¹² cm⁻², a carrier concentration higher than the carrier concentration of the electron supply layer 2d may not be obtained. When the dose of the n-type impurity is more than about 1×10¹⁶ cm⁻², crystal defects are caused by damage due to ion implantation and current collapse may be worsened. When the dose of the n-type impurity is less than about 5×10¹⁴ cm⁻², the contact resistance of the source electrode 4 and the drain electrode 5 may not be reduced. When the dose of the n-type impurity is more than about 1×10¹⁶ cm⁻², crystal defects are caused by damage due to ion implantation and device properties may be deteriorated. When setting the dose of the n-type impurity to about 5×10¹⁴ cm⁻² to 1×10¹⁶ cm⁻², a carrier concentration higher than the carrier concentration of the electron supply layer 2d is obtained without causing crystal defects and in addition the contact resistances of the source electrode 4 and the drain electrode 5 may be reduced.

As illustrated in FIG. 15C, high-concentration n-type sites 11aA, 24, and 25 are formed in the capping layer 11a. The photoresist mask 23 is removed by ashing or wet etching using a given chemical solution. The capping layer 11a is annealed. After the n-type impurity (herein, silicon) implanted in the capping layer 11a is activated, the high-concentration n-type sites 11aA, 24, and 25 are locally formed in the capping layer 11a.

The high-concentration n-type site 11aA has a carrier concentration higher than the carrier concentration of the electron supply layer 2d and an energy level lower than the Fermi energy. In the high-concentration n-type sites 24 and 25, the contact resistances of the source electrode 4 and the drain electrode 5 are reduced due to the n-type impurity. The high-concentration n-type sites 11aA, 24, and 25 are formed through one process of ion implantation and one process of annealing. Since the compound semiconductor multilayer structure 11 is formed through a relatively small number of processes, the damage of the compound semiconductor multilayer structure 11 is reduced.

As illustrated in FIGS. 1A to 3C, after an implantation mask for silicon is formed on the capping layer 11a, the n-type impurity may be ion-implanted into the capping layer 11a using the implantation mask and the photoresist mask 23.

As illustrated in FIG. 16A, an electrode recess 11A and an electrode recess 11B are formed in the planned site for the source electrode 4 and the planned site for the drain electrode 5, respectively, with the planned sites being located on a surface of the compound semiconductor multilayer structure 11. A photoresist is applied to the surface of the compound semiconductor multilayer structure 11. The photoresist is processed by lithography, whereby openings are formed in the photoresist so that surface portions of the compound semiconductor multilayer structure 11 that correspond to the planned sites (planned electrode sites) for the source electrode 4 and the drain electrode 5 are exposed through the openings. A photoresist mask having the openings is formed.

Using the photoresist mask, planned electrode sites of the capping layer 11a and the electron supply layer 2d are removed by dry etching until surface portions of the electron supply layer 2d are removed. The electrode recesses 11A and 11B are formed such that the planned electrode sites of the electron supply layer 2d are exposed. For etching conditions, an inert gas such as argon and a chlorine-based gas such as Cl₂ may be used as etching gases. For example, the flow rate of Cl₂ may be set to 30 sccm, the pressure thereof may be set to 2 Pa, and the input RF power may be set to 20 W.

The electrode recesses 11A and 11B may be formed so that the capping layer 11a is etched until intermediate portions thereof are exposed or surface portions of the electron supply layer 2d are exposed. Ion implantation may be performed as illustrated in FIG. 15B so that a peak of the concentration distribution of the n-type impurity is located on a surface exposed by dry etching. The photoresist mask is removed by ashing or the like. After processes illustrated in FIGS. 3A to 3C are performed, a device illustrated in FIG. 16B is obtained. After wiring lines are formed so as to be coupled to the source electrode 4, the drain electrode 5, and the gate electrode 6, a Schottky-type AlGaN/GaN HEMT is formed.

The high-concentration n-type site 11aA is formed in a portion (a portion next to the drain electrode 5) of the capping layer 11a that is close to the drain electrode 5. The high-concentration n-type site 24 is formed under the source electrode 4 so that the high-concentration n-type site 24 is in contact with the source electrode 4 and a peak of the concentration of the n-type impurity is located at a contact therebetween. The high-concentration n-type site 25 is formed under the source electrode 5 so that the high-concentration n-type site 25 is in contact with the drain electrode 5 and a peak of the concentration of the n-type impurity is located at a contact therebetween. The high-concentration n-type site 11aA has a carrier concentration higher than the carrier concentration of the electron supply layer 2d and an energy level lower than the Fermi energy. Therefore, electric lines of force emanating from electrons trapped on a surface of the high-concentration n-type site 11aA terminate with the high-concentration n-type site 11aA. Therefore, the influence of the electrons trapped on the high-concentration n-type site 11aA is blocked and the influence thereof on the electron supply layer 2d is reduced; hence, the reduction in concentration of a 2DEG generated in the electron supply layer 2d is reduced. The bottom surface of the source electrode 4 and the bottom surface of the drain electrode 5 are in contact with the high-concentration n-type sites 24 and 25, respectively; hence, the contact resistances of the source electrode 4 and the drain electrode 5 may be rescued.

Through a relatively small number of processes, a highly-reliable and high-voltage Schottky-type AlGaN/GaN HEMT with a relatively simple configuration in which the occurrence of current collapse, the contact resistances of the source electrode and the drain electrode and the deterioration of device properties are reduced is provided.

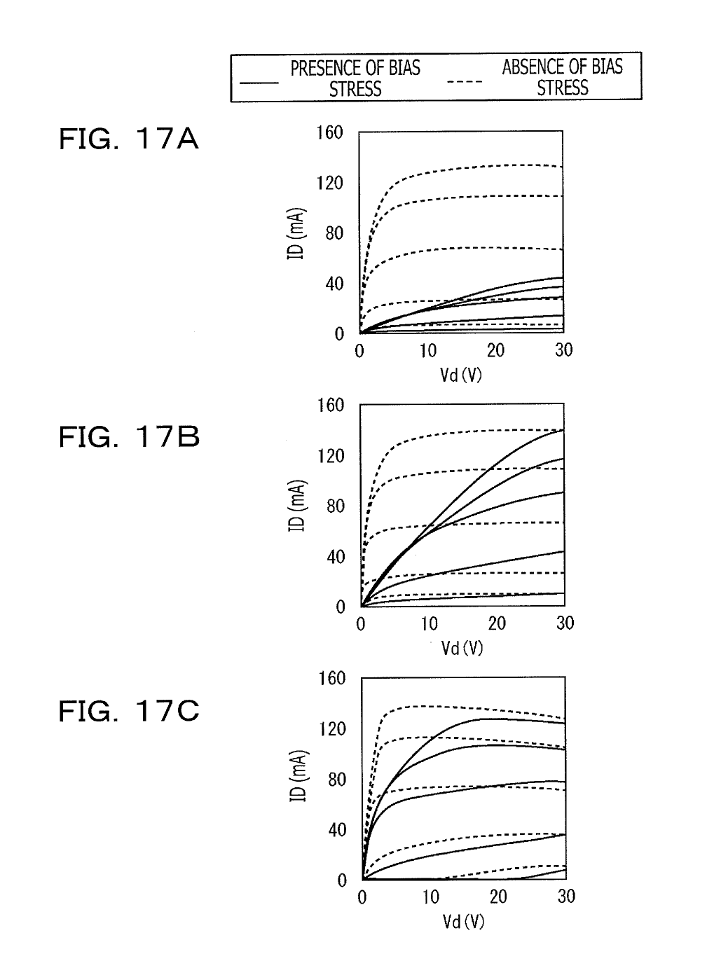

FIGS. 17A to 17C each illustrate an exemplary relationship between a drain voltage and a drain current. FIGS. 17A to 17C each illustrate the relationship between the drain voltage (Vd) and drain current (Id) of an AlGaN/GaN HEMT in pulse operation. The case where bias stress is present in an off mode and the case where bias stress is absent are illustrated therein. As bias stress in an off mode, a negative bias (Vgs=−3 V, Vds=50 V) is applied to the gate electrode for 1 ms. An on-voltage is applied to the gate electrode for 1 μs and the drain circuit is measured at that time. FIG. 17A illustrates, for example, the relationship obtained for an AlGaN/GaN HEMT illustrated in FIG. 15C. FIG. 17B illustrates the relationship obtained for an AlGaN/GaN HEMT that includes a capping layer with a monolayer structure. FIG. 17C illustrates the relationship obtained for an AlGaN/GaN HEMT that includes a capping layer with a three-layer structure.

With the AlGaN/GaN HEMT illustrated in FIG. 17A, when Vd is large, Id in the case where bias stress is present is lower than Id in the case where bias stress is absent; hence, current collapse may occur. With the AlGaN/GaN HEMT illustrated in FIG. 17B, when Vd is large, Id in the case where bias stress is present is lower than Id in the case where bias stress is absent; hence, the occurrence of current collapse may be reduced. With the AlGaN/GaN HEMT illustrated in FIG. 17C, when Vd is large, there is relatively little difference between Id in the case where bias stress is absent and Id in the case where bias stress is present; hence, the occurrence of current collapse may be sufficiently reduced.

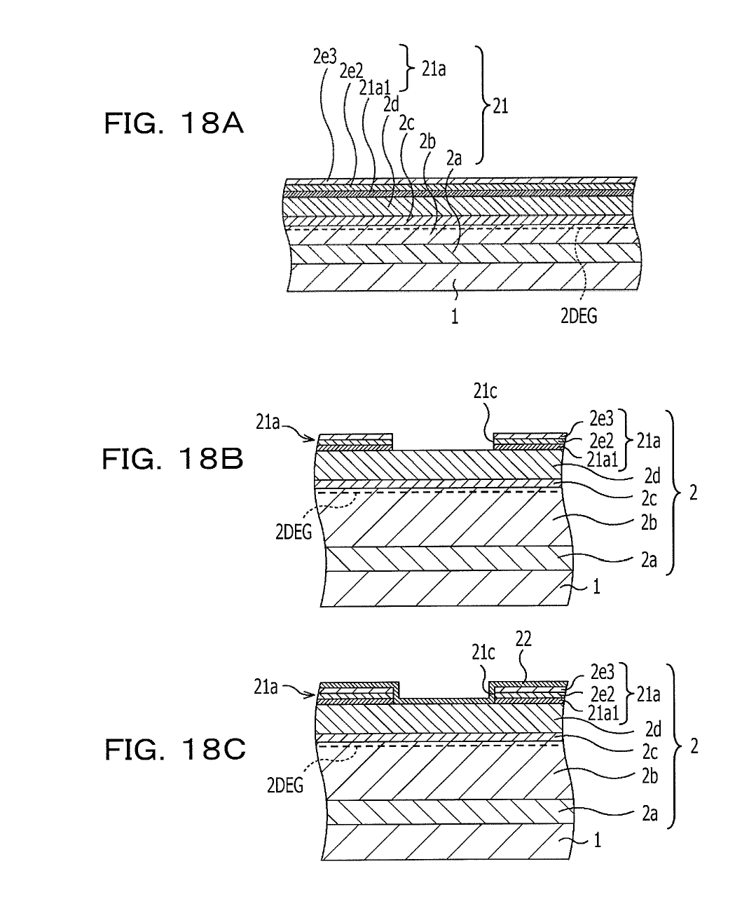

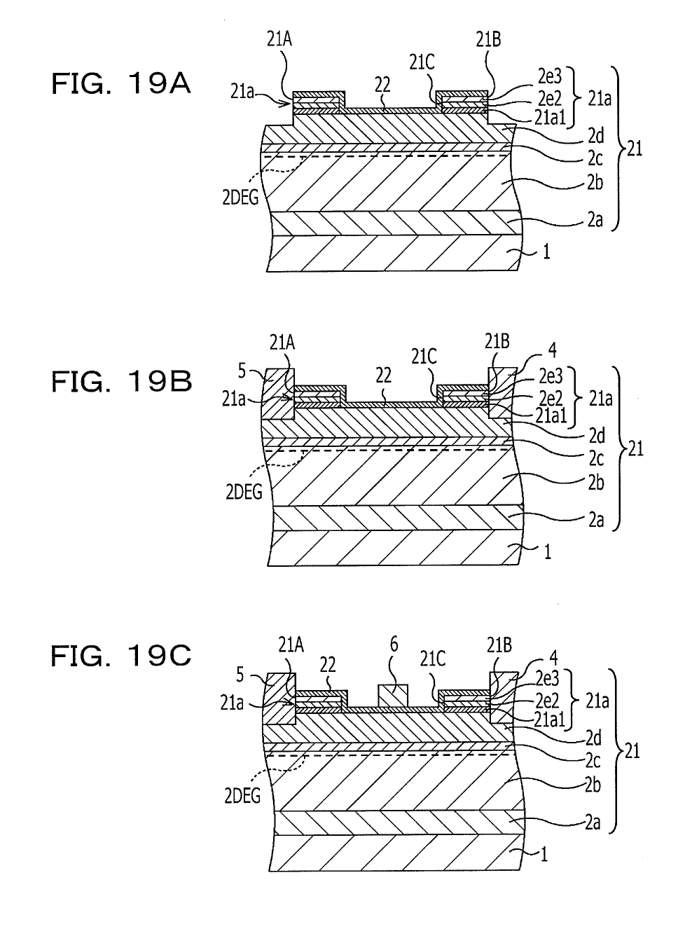

FIGS. 18A to 18C and 19A to 19C illustrate an exemplary method for manufacturing a compound semiconductor device. The compound semiconductor device illustrated in FIGS. 18A to 19C may be a MIS-type AlGaN/GaN HEMT.

As illustrated in FIG. 18A, a compound semiconductor multilayer structure 21 is formed on an SiC substrate 1. In the compound semiconductor multilayer structure 21, similar to the compound semiconductor multilayer structure 2 described in the first embodiment, a buffer layer 2a, an electron transit layer 2b, an intermediate layer 2c, and an electron supply layer 2d are formed in that order. A capping layer 21a is formed on the electron supply layer 2d instead of a capping layer 2e. In the capping layer 21a, an n⁺-GaN sub-layer 21a1 containing a high concentration of an n-type impurity, for example silicon; an AlN sub-layer 2e2 similar to that of the capping layer 2e; and an n-GaN sub-layer 2e3 similar to that of the capping layer 2e are deposited in that order.

As similar to the n-GaN sub-layer 2e1 of the capping layer 2e, a mixture of TMGa gas and NH₃ gas is used as a source gas to form the n⁺-GaN sub-layers 21a1. SiH₄ gas is added to the source gas at a given flow rate and therefore the GaN is doped with silicone. The doping concentration of silicone may be about 3×10¹⁸ cm⁻³ to 1×10¹⁹ cm⁻³, for example about 1×10¹⁹ cm⁻³. The doped n-type impurity may be germanium, oxygen, or the like instead of silicone. When the doping concentration of the n-type impurity is less than about 3×10¹⁸ cm⁻³, a carrier concentration higher than the carrier concentration of the electron supply layer 2d may not be obtained. When the doping concentration of the n-type impurity is more than about 1×10¹⁹ cm⁻³, high carrier concentration may not be obtained. When setting the doping concentration of the n-type impurity to about 3×10¹⁸ cm⁻³ to 1×10¹⁹ cm⁻³, the occurrence of crystal defects is reduced and a carrier concentration higher than the carrier concentration of the electron supply layer 2d may be obtained.

As illustrated in FIG. 18B, an electrode recess 21C is formed in a region of the capping layer 21a that includes a planned site for a gate electrode 6. A photoresist is applied to a surface of the compound semiconductor multilayer structure 21. After the photoresist is processed by lithography, an opening is formed in the photoresist so that a surface portion of the compound semiconductor multilayer structure 21 that corresponds to the planned site (planned electrode site) for the gate electrode 6 is exposed through the opening. A photoresist mask having the opening is formed.

Using the photoresist mask, a planned electrode site of the capping layer 21a is removed by dry etching. The electrode recess 21C is formed such that a surface region of the electron supply layer 2d that includes the planned electrode site is exposed. For etching conditions, an inert gas such as argon and a chlorine-based gas such as Cl₂ may be used as etching gases. For example, the flow rate of Cl₂ may be set to 30 sccm, the pressure thereof may be set to 2 Pa, and the input RF power may be set to 20W. The photoresist mask is removed by ashing or the like.

The range of the electrode recess 21C may be determined depending on the breakdown voltage of the gate electrode 6. The larger the distance between the gate electrode 6 and the n⁺-GaN sub-layers 21a1 of the capping layer 21a, the higher the breakdown voltage of the gate electrode 6.

As illustrated in FIG. 18C, a gate insulating layer 22 is formed. For example, Al₂O₃ is deposited as an insulating material on the capping layer 21a so as to cover the inner surface of the electrode recess 21C. For the deposition of Al₂O₃, for example, an atomic layer deposition (ALD) process may be used and TMAI gas and O₃ are alternately supplied. Al₂O₃ may be deposited to a thickness of about 2 nm to 200 nm, for example about 30 nm. The gate insulating layer 22 is formed

For example, a plasma-enhanced chemical vapor deposition (PECVD) process, a sputtering process, or the like may be used for the deposition of Al₂O₃ instead of the ALD process. Aluminium nitride or aluminium oxynitride may be used instead of Al₂O₃. The gate insulating layer 22 may be formed by depositing an oxide, nitride, or oxynitride of silicon, hafnium, zirconium, titanium, tantalum, or tungsten, or may be formed in such a manner that some selected oxides, nitrides, and oxynitrides of silicon, hafnium, zirconium, titanium, tantalum, and tungsten are deposited to form a multilayer structure.

As illustrated in FIG. 19A, an electrode recess 21A and an electrode recess 21B are formed in a planned site for a source electrode 4 and a planned site for a drain electrode 5, respectively, the planned sites being located on a surface of the compound semiconductor multilayer structure 21. A photoresist is applied to the gate insulating layer 22. After the photoresist is processed by lithography, openings are formed in the photoresist so that surface portions of the compound semiconductor multilayer structure 2 that correspond to the planned sites (planned electrode sites) for the source electrode 4 and the drain electrode 5 are exposed through the openings. A photoresist mask having the openings is formed.

Using the photoresist mask, planned electrode sites of the gate insulating layer 22, the capping layer 21a and the electron supply layer 2d are removed by dry etching until surface portions of the electron supply layer 2d are removed. The electrode recesses 21A and 21B are formed so that the planned electrode sites of the electron supply layer 2d are exposed. For etching conditions, an inert gas such as argon and a chlorine-based gas such as Cl₂ are used as etching gases. For example, the flow rate of Cl₂ may be set to 30 sccm, the pressure thereof may be set to 2 Pa, and the input RF power may be set to 20 W. The electrode recesses 21A and 21B may be formed so that the capping layer 21a is etched until intermediate portions thereof are exposed or surface portions of the electron supply layer 2d are exposed. The photoresist mask is removed by ashing or the like.

As illustrated in FIG. 19B, the source electrode 4 and the drain electrode 5 are formed. A photoresist mask for forming the source electrode 4 and the drain electrode 5 is formed. For example, a two-layer resist, which has a visor structure and is suitable for a vapor deposition process and a lift-off process, is used to form the photoresist mask. The photoresist is applied to the gate insulating layer 22 and the compound semiconductor multilayer structure 21 and openings exposing the electrode recesses 21A and 21B are formed therein. The photoresist mask is formed so as to have the openings. An electrode material, for example titanium and aluminium, is deposited over the photoresist mask, which has the openings that expose the electrode recesses 21A and 21B, by the vapor deposition process. A layer of Ti may have a thickness of about 10 nm. A layer of Al may have a thickness of about 300 nm. The photoresist mask and titanium and aluminium deposited thereon are removed by the lift-off process. After the SiC substrate 1 is heat-treated at a temperature of about 400° C. to 1,000° C., for example about 600° C., in a nitrogen atmosphere, the remaining titanium and aluminium makes ohmic contact with the electron supply layer 2d. When ohmic contact between titanium and aluminium and the electron supply layer 2d is obtained, heat treatment may be omitted. The electrode recesses 21A and 21B are filled with portions of the electrode material, whereby the source electrode 4 and the drain electrode 5 are formed.

As illustrated in FIG. 19C, the gate electrode 6 is formed. A photoresist mask for forming the gate electrode 6 is formed. A two-layer resist, which has a visor structure and is suitable for a vapor deposition process and a lift-off process, is used to form the photoresist mask. After the photoresist is applied to the gate insulating layer 22, an opening is formed in the photoresist so that a portion of the gate insulating layer 22 that corresponds to the electrode recess 21C is exposed through the opening. A photoresist mask having the opening is formed.

An electrode material, for example nickel and gold, is deposited over the photoresist mask, which has an opening that exposes the electrode recess 21C, by the vapor deposition process. A layer of nickel may have a thickness of about 30 nm. A layer of gold may have a thickness of about 400 nm. The photoresist mask and nickel and gold deposited thereon are removed by the lift-off process. The electrode recess 21C is filled with a portion of the electrode material, whereby the gate electrode 6 is formed above the electron supply layer 2d with the gate insulating layer 22 therebetween.

After wiring lines are formed so as to be coupled to the source electrode 4, the drain electrode 5, and the gate electrode 6, a MIS-type AlGaN/GaN HEMT is formed.

The capping layer 21a with a three-layer structure is used and the n⁺-GaN sub-layers 21a1, which corresponds to a portion on the drain electrode side 5 of the capping layer 21a, is set to a locally high-concentration n-type site. The high-concentration n-type site has a carrier concentration higher than the carrier concentration of the electron supply layer 2d and an energy level lower than the Fermi energy. Therefore, electric lines of force emanating from electrons trapped on a surface of the high-concentration n-type site terminate with the high-concentration n-type site. The influence of the electrons trapped on the high-concentration n-type site 2eA is blocked, the influence thereof on the electron supply layer 2d is reduced and the reduction in concentration of a 2DEG generated in the electron supply layer 2d is reduced.

A highly-reliable and high-voltage Schottky-type AlGaN/GaN HEMT with a relatively simple configuration in which the occurrence of current collapse and the deterioration of device properties are reduced is provided.

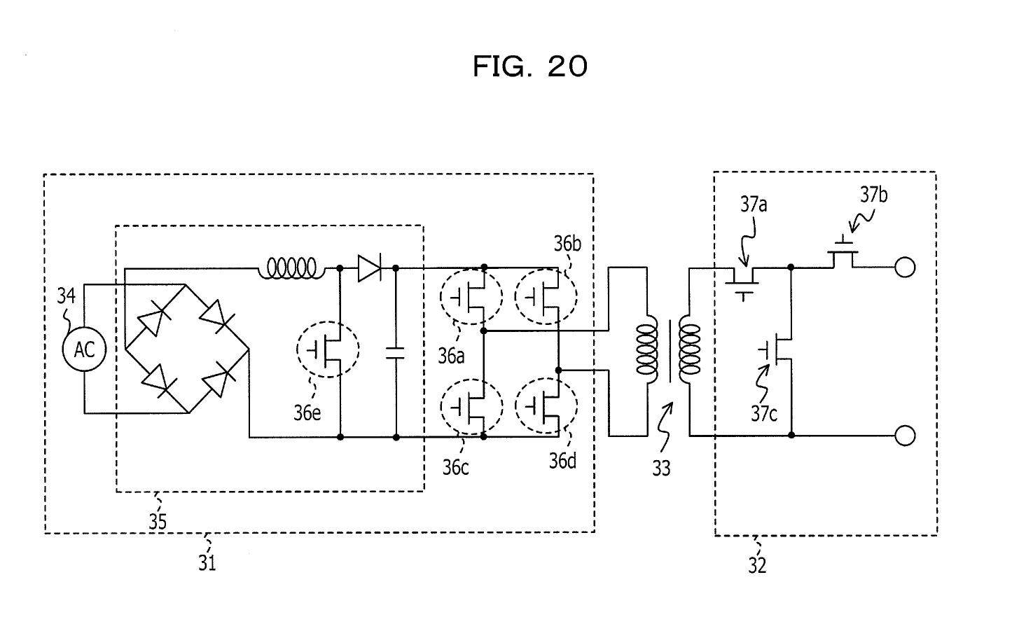

FIG. 20 illustrates an exemplary power supply apparatus. The power supply system illustrated in FIG. 20 may include the above-mentioned AlGaN/GaN HEMT.

The power supply system includes a high-voltage primary circuit 31, a low-voltage secondary circuit 32, and a transformer 33 provided between the primary circuit 31 and the secondary circuit 32. The primary circuit 31 includes an alternating-current power supply 34, a bridge rectifier circuit 35, and a plurality of switching elements, for example, four switching elements 36a, 36b, 36c, and 36d. The bridge rectifier circuit 35 includes a switching element 36e. The secondary circuit 32 includes a plurality of switching elements, for example, three switching elements 37a, 37b, and 37c.

The switching elements 36a, 36b, 36c, 36d, and 36e of the primary circuit 31 may be the same as the above-mentioned AlGaN/GaN HEMT. The switching elements 37a, 37b, and 37c of the secondary circuit 32 may be MISFETs that contain silicon.

A highly-reliable and high-voltage Schottky-type AlGaN/GaN HEMT with a relatively simple configuration in which the occurrence of current collapse and the deterioration of device properties are reduced may be applied to the primary circuit 31: a MIS-type highly-reliable, high-voltage AlGaN/GaN HEMT that has a relatively simple configuration to suppress the occurrence of current collapse and in which the deterioration of device properties is reduced.

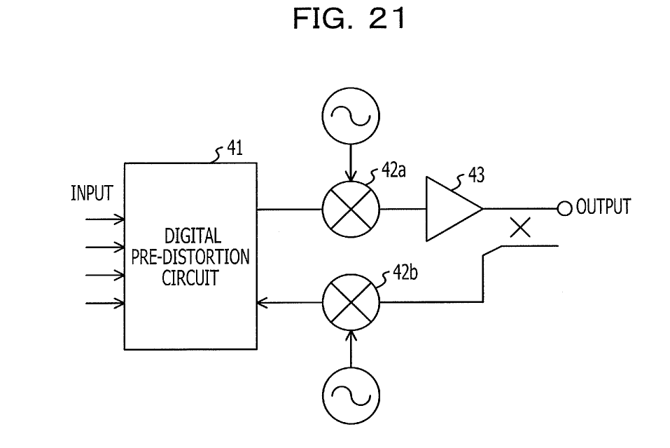

FIG. 21 illustrates an exemplary high-frequency amplification unit. An AlGaN/GaN HEMT may be applied to the high-frequency amplification unit illustrated in FIG. 21.

The high-frequency amplifier includes a digital pre-distortion circuit 41, mixers 42a and 42b, and a power amplifier 43. The digital pre-distortion circuit 41 compensates for nonlinear distortion of an input signal. The mixer 42a mixes an alternating-current signal with the input signal whose nonlinear distortion is compensated for. The power amplifier 43 amplifies the input signal mixed with the alternating-current signal and may include an AlGaN/GaN HEMT. For example, an output signal is mixed with the alternating-current signal by the mixer 42b and is transmitted to the digital pre-distortion circuit 41 by switching.

A highly-reliable and high-voltage Schottky-type AlGaN/GaN HEMT with a relatively simple configuration in which the occurrence of current collapse and the deterioration of device properties are reduced is applied to the high-frequency amplification unit. Therefore, a high-reliability, high-voltage high-frequency amplification unit is provided.

A compound semiconductor device may be an AlGaN/GaN HEMT or another HEMT.

A compound semiconductor device may include an InAlN/GaN-HEMT as another HEMT. InAlN and GaN have, depending on the composition thereof, lattice parameters that are close to each other. An electron transit layer may be made of i-GaN, an intermediate layer may be made of i-InAlN, and an electron supply layer may be made of n-InAlN. A capping layer may have a three-layer structure including an n-GaN sub-layer, an AlN sub-layer, and an n-GaN sub-layer; a monolayer structure of n-GaN; or a three-layer structure including an n⁺-GaN sub-layer, an AlN sub-layer, and an n-GaN sub-layer. Since substantially no piezoelectric polarization occurs, a two-dimensional electron gas may be generated by the spontaneous polarization of InAlN.

Like the AlGaN/GaN HEMT, a highly-reliable and high-voltage Schottky-type InGaN/GaN HEMT with a relatively simple configuration in which the occurrence of current collapse and the deterioration of device properties are reduced is obtained.

A compound semiconductor device includes an InAlGaN/GaN HEMT. GaN has lattice parameters that may be less than those of InAlGaN depending on the composition thereof. An electron transit layer may be made of i-GaN, an intermediate layer may be made of i-InAlGaN, and an electron supply layer may be made of n-InAlGaN. A capping layer may have a three-layer structure including an n-GaN sub-layer, an AlN sub-layer, and an n-GaN sub-layer; a monolayer structure of n-GaN; or a three-layer structure including an n⁺-GaN sub-layer, an AlN sub-layer, and an n-GaN sub-layer.

Like the AlGaN/GaN HEMT, a highly-reliable and high-voltage Schottky-type InGaN/GaN HEMT with a relatively simple configuration in which the occurrence of current collapse and the deterioration of device properties are reduced is obtained.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A compound semiconductor device comprising:
a first compound semiconductor layer in which carriers are formed;
a second compound semiconductor layer, provided above the first compound semiconductor layer, to supply the carriers; and
a third compound semiconductor layer provided above the second compound semiconductor layer,
wherein the third compound semiconductor layer includes a area that has a carrier concentration higher than a carrier concentration of the second compound semiconductor layer.

2. The compound semiconductor device according to claim 1,
wherein the area has an energy level lower than the Fermi energy.

3. The compound semiconductor device according to claim 1,
wherein the area is doped with an n-type impurity at a given concentration.

4. The compound semiconductor device according to claim 1,
wherein the area is a lower portion of the third compound semiconductor layer.

5. The compound semiconductor device according to claim 1,
wherein the third compound semiconductor layer includes a first GaN sub-layer, an AlN layer, and a second GaN layer deposited in that order.

6. The compound semiconductor device according to claim 5,
wherein the area is formed in the first GaN sub-layer.

7. The compound semiconductor device according to claim 1, further comprising:
a first electrode placed above a compound semiconductor multilayer structure including the first compound semiconductor layer, the second compound semiconductor layer and the a third compound semiconductor layer; and
a pair of second electrodes provided on the compound semiconductor multilayer structure, each of the pair of second electrodes being provided on corresponding side of the first electrode,
wherein the area of the third compound semiconductor layer is provided between the first electrode and one of the pair of second electrodes.

8. The compound semiconductor device according to claim 1, further comprising:
a first electrode placed above a compound semiconductor multilayer structure including that includes the first compound semiconductor layer, the second compound semiconductor layer and the third compound semiconductor layer; and
a pair of second electrodes provided on the compound semiconductor multilayer structure, each of the pair of second electrodes being provided on corresponding side of the first electrode,
wherein a portion of the compound semiconductor multilayer structure under at least one electrode among the first electrode and the pair of second electrodes is doped with an n-type impurity.

9. The compound semiconductor device according to claim 7,
wherein the area is formed on the side of at least one electrode of the pair of second electrodes, and the first electrode is formed over a recess of the third compound semiconductor with an insulating layer.

10. A method for manufacturing a compound semiconductor device, comprising:
forming a first compound semiconductor layer in which carriers are formed;
forming, above the first compound semiconductor layer, a second compound semiconductor layer to supply the carriers;
forming, above the second compound semiconductor layer, a third compound semiconductor layer to form a compound semiconductor multilayer structure including the first compound semiconductor layer, the second compound semiconductor layer and the third semiconductor layer; and
forming a area in the third compound semiconductor layer having a carrier concentration higher than the carrier concentration of the second compound semiconductor layer.

11. The method according to claim 10,
wherein the area has an energy level lower than the Fermi energy.

12. The method according to claim 10, further comprising,
doping an n-type impurity into the third compound semiconductor layer at a given concentration to form the area.

13. The method according to claim 10,
wherein the area is formed in a lower portion of the third compound semiconductor layer.

14. The method according to claim 10, further comprising,
depositing a first GaN sub-layer, an AlN layer, and a second GaN layer in that order to form the third compound semiconductor layer.

15. The method according to claim 14,
wherein the area is formed in the first GaN layer.

16. The method according to claim 10, further comprising:
forming a first electrode above the compound semiconductor multilayer structure;
forming a pair of second electrodes so that each of the pair of the second electrode is provided in the corresponding side of the first electrode; and
forming the area between the first electrode and one of the pair of second electrodes.

17. The method according to claim 10, further comprising:
forming a first electrode above the compound semiconductor multilayer structure;
forming a pair of second electrodes so that each of the pair of the second electrode is provided in the corresponding side of the first electrode; and
doping a portion of the compound semiconductor multilayer structure under at least one electrode among the first electrode and the pair of second electrodes with an n-type impurity.

18. The method according to claim 16, further comprising:
forming an opening in the third compound semiconductor layer;
forming the area on the side of at least one electrode of the pair of second electrodes; and
forming the first electrode over the opening with an insulating layer.

19. An electronic circuit comprising:
a circuit including a transistor,
wherein the transistor includes:
a first compound semiconductor layer in which carriers are formed;
a second compound semiconductor layer, provided above the first compound semiconductor layer, to supply the carriers; and
a third compound semiconductor layer provided above the second compound semiconductor layer,
wherein the third compound semiconductor layer includes a area that has a carrier concentration higher than a carrier concentration of the second compound semiconductor layer.

20. The electronic circuit according to claim 19 wherein the electronic circuit is a power supply circuit including a high-voltage circuit, a low-voltage circuit, and a transformer sandwiched between the high-voltage circuit and the low-voltage circuit, or a high-frequency amplification unit to amplify an input high-frequency voltage.
